(19) United States
(12) Patent Application Publication
(10) Pub. No.: US 2013/0230802 A1
(43) Pub. Date: Sep. 5, 2013

(54) ACRYLAMIDE DERIVATIVE, POLYMER COMPOUND AND PHOTORESIST COMPOSITION

(71) Applicants: Ichihiro Aratani, Niigata (JP); Takashi Fukumoto, Niigata (JP)

(72) Inventors: Ichihiro Aratani, Niigata (JP); Takashi Fukumoto, Niigata (JP)

(73) Assignee: KURARAY CO., LTD., Kurashiki-shi, Okayama (JP)

(21) Appl. No.: 13/876,298

(22) PCT Filed: Aug. 25, 2011
(86) PCT No.: PCT/JP2011/069213

§ 371 Date: May 16, 2013

(30) Foreign Application Priority Data
Sep. 29, 2010 (JP) 2010-220054

(51) Int. Cl. G03F 7/004

(52) U.S. Cl. CPC G03F 7/004
USPC 430/270.1; 526/257; 526/270; 549/31; 549/300

(57) ABSTRACT

To provide an acrylamide derivative which can form a structural unit of a polymer to be incorporated into a photoresist composition, a polymer produced through polymerization of a raw material containing the acrylamide derivative, and a photoresist composition which contains the polymer and which, as compared with the case of conventional ones, realizes formation of a high-resolution resist pattern having improved LWR. The invention provides an acrylamide derivative represented by the following formula (1):

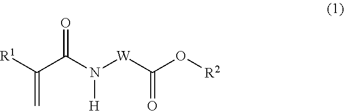

wherein R¹ represents a hydrogen atom, a methyl group, or a trifluoromethyl group; W represents a C1 to C10 alkylene group or a C3 to C10 cycloalkylene group; R² represents a cyclic group having 3 to 20 ring-forming atoms and represented by the following formula (2):

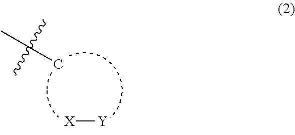

wherein X represents an oxygen atom or >N—R³; R³ represents a hydrogen atom or a C1 to C5 alkyl group; Y represents >C═O or >S(═O)ₙ; and n is an integer of 0 to 2.

### FIELD OF THE INVENTION

The present invention relates to an acrylamide derivative; a polymer produced through polymerization of a raw material containing the acrylamide derivative; and a photoresist composition which realizes formation of a high-resolution resist pattern having improved line width roughness (LWR).

### BACKGROUND ART

Lithography involves a process in which, for example, a resist film is formed from a resist material on a substrate; the resist film is subjected to selective light exposure by a radiation such as light or electron beam via a mask having a specific pattern; and the exposed resist film is developed, to thereby form a specific resist pattern on the film. As used herein, the term “positive tone resist material” refers to a resist material which, when exposed to light, dissolves in a developer, and the term “negative tone resist material” refers to a resist material which, when exposed to light, does not dissolve in a developer.

In recent years, with the progress of lithography techniques, micro-patterning has been rapidly developed in production of semiconductor devices or liquid crystal display devices. Generally, miniaturization of patterning is carried out by use of an exposure light source of short wavelength (higher energy). Hitherto, ultraviolet rays such as g-ray and i-ray have been used for lithography. Recently, KrF excimer laser or ArF excimer laser has been used for mass production of semiconductor devices. Also, attempts have been made to use, in lithography, F₂ excimer laser, electron beams, EUVs (extreme ultraviolet rays), X-rays, etc. having a shorter wavelength (higher energy) as compared with KrF excimer laser or ArF excimer laser.

A resist material is required to exhibit various lithographic properties, including sensitivity to such an exposure light source, and resolution which realizes reproduction of micro-patterning. A resist material satisfying these requirements is, for example, a chemically amplified resist composition containing a base component whose solubility in an alkaline developer changes through the action of an acid, and a photoacid generator component which generates an acid through light exposure.

For example, a generally used chemically amplified positive tone resist composition contains a resin component (base resin) whose solubility in an alkaline developer increases through the action of an acid, and a photoacid generator component. In the case where a resist film is formed from such a resist composition, when the resist film is subjected to selective light exposure during formation of a resist pattern, an acid is generated from the photoacid generator component at an exposed portion of the film, and the solubility of the resin component in an alkaline developer increases through the action of the acid, whereby the exposed portion becomes soluble in the alkaline developer.

A photoresist composition which is currently used for, for example, ArF excimer laser lithography generally contains, as a base resin component, a resin having a main chain formed of a structural unit derived from a (meth)acrylic ester; i.e., an acrylic resin, since the resin exhibits excellent transparency at 193 nm or thereabout. As has been known, a photoresist composition incorporating a polymer containing a structural unit having norbornane lactone exhibits high etching resistance and improved adhesion to a substrate (see Patent Document 1). There has also been proposed, for example, a polymer for a photoresist composition, the polymer containing a structural unit having a norbornane lactone skeleton or norbornane sultone skeleton to which an acryloyloxy group is bonded via a linkage group (see Patent Document 2 or 3).

### PRIOR ART DOCUMENT

### Patent Document

Patent Document 1: Japanese Patent Application Laid-Open (kokai) No. 2000-26446
Patent Document 2: Japanese Patent Application Laid-Open (kokai) No. 2001-188346
Patent Document 3: International Patent Publication WO 2010/001913

### SUMMARY OF THE INVENTION

### Problems to be Solved by the Invention

As described above, in recent years, with the progress of lithography techniques, micro-patterning has been rapidly developed in production of semiconductor devices or liquid crystal display devices. In connection therewith, keen demand has arisen for development of a resist material which realizes further improved lithographic properties, including resolution and line width roughness (LWR), as well as further improved patterning. Therefore, it is important to develop a novel acrylic ester derivative which can form a structural unit of a polymer to be incorporated into a photoresist composition.

In view of the foregoing, an object of the present invention is to provide a novel acrylamide derivative which can form a structural unit of a polymer to be incorporated into a photoresist composition. Another object of the present invention is to provide a polymer produced through polymerization of a raw material containing the acrylamide derivative. Yet another object of the present invention is to provide a photoresist composition which contains the polymer and which, as compared with the case of conventional ones, realizes formation of a high-resolution resist pattern having improved LWR.

### Means for Solving the Problems

The present inventors have conducted extensive studies, and as a result have found that a photoresist composition containing a polymer produced through polymerization of a raw material containing an acrylamide derivative having a specific structure realizes formation of a high-resolution resist pattern having improved LWR, as compared with the case of conventional photoresist compositions.

Accordingly, the present invention provides the following [1] to [4].

An acrylamide derivative represented by the following formula (1):

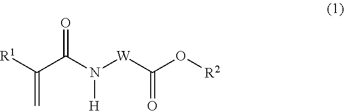

wherein R¹ represents a hydrogen atom, a methyl group, or a trifluoromethyl group; W represents a C1 to C10 alkylene group or a C3 to C10 cycloalkylene group; R² represents a cyclic group having 3 to 20 ring-forming atoms and represented by the following formula (2):

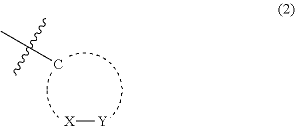

wherein X represents an oxygen atom or >N—R³; R³ represents a hydrogen atom or a C1 to C5 alkyl group; Y represents >C═O or >S(═O)ₙ; and n is an integer of 0 to 2.

[2] An acrylamide derivative according to [1] above, which is represented by the following formula (3):

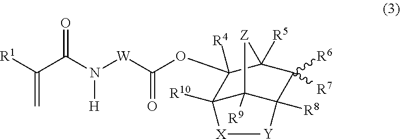

wherein R¹, W, X, and Y have the same meanings as defined above; each of R⁴, R⁵, R⁶, R⁸, R⁹, and R¹⁰ represents a hydrogen atom, a C1 to C6 alkyl group, a C3 to C6 cycloalkyl group, a C1 to C6 alkoxy group, or an ester group; R⁷ represents a hydrogen atom, a C1 to C6 alkyl group, a C3 to C6 cycloalkyl group, a C1 to C6 alkoxy group, or —COOR^{a}; R^{a} represents a C1 to C3 alkyl group; Z represents a methylene group, an oxygen atom, or a sulfur atom; and the wavy lines represent that either R⁶ or R⁷ may be in an endo or exo position

[3]A polymer produced through polymerization of a raw material containing an acrylamide derivative as recited in [1] or [2] above.

[4] A photoresist composition comprising a polymer as recited in [3] above, a photoacid generator, and a solvent.

### Effects of the Invention

A photoresist composition containing a polymer produced through polymerization of a raw material containing the acrylamide derivative of the present invention realizes formation of a high-resolution resist pattern having improved LWR.

### MODES FOR CARRYING OUT THE INVENTION

### [Acrylamide Derivative (1)]

An acrylamide derivative represented by the following formula (1) (hereinafter may be referred to as “acrylamide derivative (1)”) is useful for producing a photoresist composition which realizes improvement of LWR.

A characteristic feature of the acrylamide derivative (1) resides in that it has a specific cyclic structure at the molecular end, and the cyclic structure is bonded to a polymerizable group by the mediation of an amido bond. A photoresist composition containing a polymer produced through polymerization of a raw material containing the acrylamide derivative realizes formation of a high-resolution resist pattern having improved LWR, as compared with the case of conventional photoresist compositions. The reason why the effects of the present invention are obtained has not yet been elucidated. However, a conceivable reason is that the length of diffusion of an acid generated from a photoacid generator is appropriately reduced through interaction between the acid and both a polar group included in the end cyclic structure of the acrylamide derivative (1) of the present invention and an amido bond.

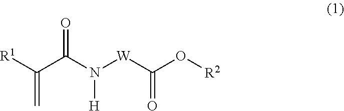

R¹ represents a hydrogen atom, a methyl group, or a trifluoromethyl group. Of these, a hydrogen atom or a methyl group is preferred.

W represents a C1 to C10 alkylene group or a C3 to C10 cycloalkylene group. Examples of the alkylene group include methylene, ethylene, propylene, butylene, trimethylene, pentamethylene, octamethylene, and decamethylene. Examples of the cycloaklylene group include a cyclopentane-1,2-diyl group and a cyclohexane-1,2-diyl group. Of these, W is preferably a C1 to C10 alkylene group, with a C1 to C5 alkylene group being more preferred, a C1 to C3 alkylene group being still more preferred, methylene group being particularly preferred.

R² represents a cyclic group having 3 to 20 ring-forming atoms and represented by the following formula (2).

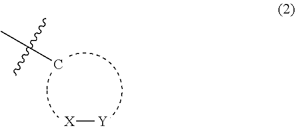

X in formula (2) represents an oxygen atom or >N—R³. R³ represents a hydrogen atom or a C1 to C5 alkyl group. The C1 to C5 alkyl group represented by R³ may be a linear-chain group or a branched group, and examples thereof include methyl, ethyl, n-propyl, isopropyl, n-butyl, isobutyl, s-butyl, t-butyl, and n-pentyl. Of these, a C1 to C4 alkyl group is preferred, with a branched C3 or C4 alkyl group being more preferred, a t-butyl group being still more preferred. R³ is preferably a hydrogen atom or a t-butyl group.

Y in formula (2) represents >C═O or >S(═O)ₙ; and n is an integer of 0 to 2. The “n” is preferably 1 or 2, more preferably 2.

No particular limitation is imposed on the combination of X and Y in formula (2). When X is an oxygen atom, Y may be >C═O or >S(═O)ₙ. When X is >N—R³, Y may be >C═O or >S(═O)ₙ. Particularly when X is an oxygen atom, and Y is >S(═O)ₙ, LWR and resolution can be more effectively improved.

For improving LWR and resolution, the cyclic group having 3 to 20 ring-forming atoms and represented by the following formula (2) preferably has a norbornane structure. The number of ring-forming atoms is preferably 5 to 10. Among acrylamide derivatives represented by formula (1), those represented by formula (3) are preferred.

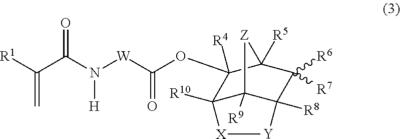

R¹, W, X, Y, and the wavy lines in formula (3) have the same meanings as defined above, and preferred members are the same as described above.

Z represents a methylene group, an oxygen atom, or a sulfur atom. For improving LWR and resolution, Z is preferably a methylene group or an oxygen atom.

Each of R⁴, R⁵, R⁶, R⁸, R⁹, and R¹⁰ represents a hydrogen atom, a C1 to C6 alkyl group, a C3 to C6 cycloalkyl group, or a C1 to C6 alkoxy group.

The C1 to C6 alkyl group may be a linear-chain group or a branched group, and examples thereof include methyl, ethyl, n-propyl, isopropyl, n-butyl, isobutyl, s-butyl, n-pentyl, and n-hexyl. Of these, a C1 to C3 alkyl group is preferred.

Examples of the C3 to C6 cycloalkyl group include cyclopropyl, cyclobutyl, cyclopentyl, and cyclohexyl.

The C1 to C6 alkoxy group may be a linear-chain group or a branched group, and examples thereof include methoxy, ethoxy, n-propoxy, isopropoxy, n-butoxy, isobutoxy, t-butoxy, n-pentyloxy, and n-hexyloxy. Of these, a C1 to C3 alkoxy group is preferred.

Among them, each of R⁴, R⁵, R⁶, R⁸, R⁹, and R¹⁰ is preferably a hydrogen atom, a C1 to C3 alkyl group, or a C1 to C3 alkoxy group, with a hydrogen atom being more preferred.

R⁷ represents a hydrogen atom, a C1 to C6 alkyl group, a C3 to C6 cycloalkyl group, a C1 to C6 alkoxy group, or —COOR^{a}. R^{a} represents a C1 to C3 alkyl group. Examples of the C1 to C6 alkyl group, the C3 to C6 cycloalkyl group, and the C1 to C6 alkoxy group are the same as exemplified in relation to R⁴, R⁵, R⁶, R⁸, R⁹, and R¹⁰, and preferred members are the same as described above.

Examples of the C1 to C3 alkyl group represented by R^{a} include methyl, ethyl, n-propyl, and isopropyl.

In formula (3), the wavy lines represent that either R⁶ or R⁷ may be in an endo or exo position. Particularly, R⁷ is preferably in an endo position.

Specific examples of the acrylamide derivative (1) are the following, but are not limited to them.

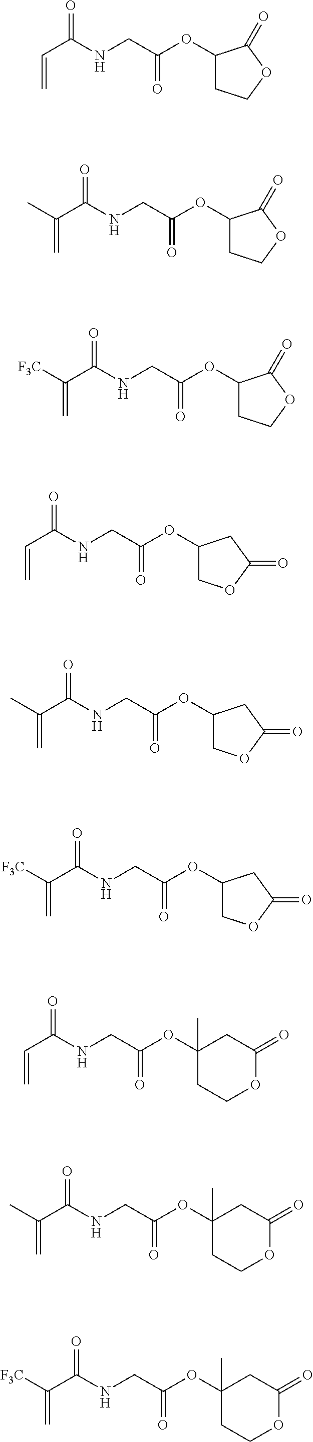

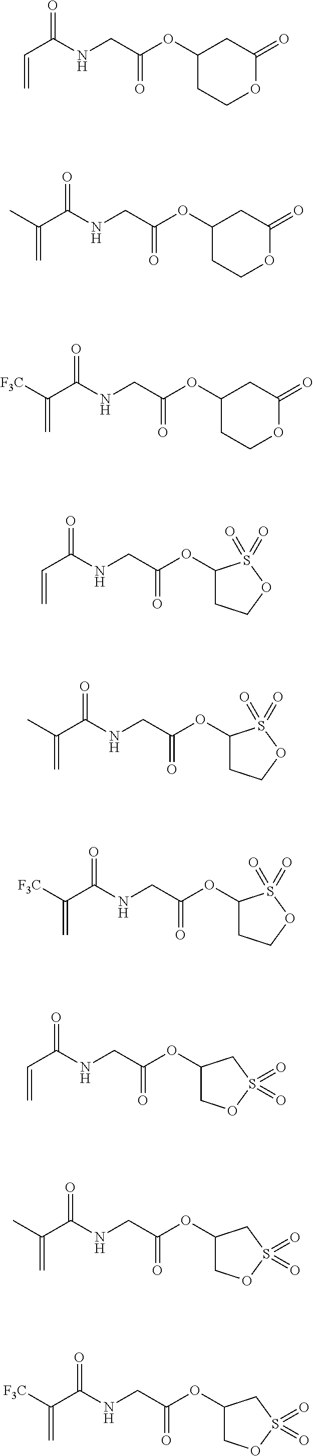

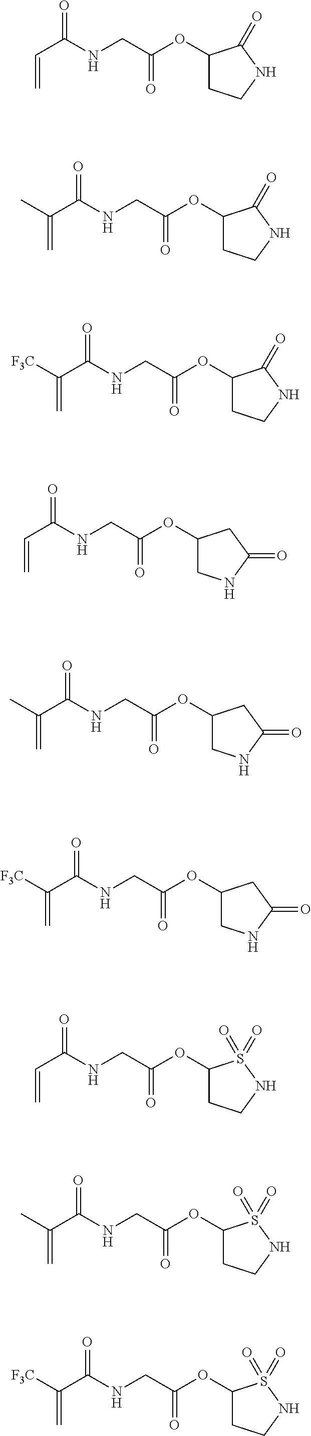

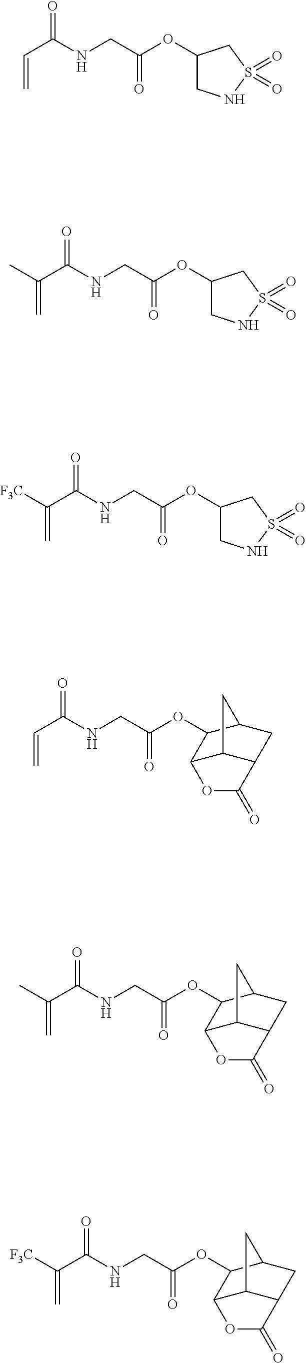 [SMILES: C=CC(=O)NCC(=O)OC1CNS(=O)(=O)C1 ; C=C(C)C(=O)NCC(=O)OC1CNS(=O)(=O)C1 ; C=C(C(=O)NCC(=O)OC1CNS(=O)(=O)C1)C(F)(F)F ; C=CC(=O)NCC(=O)OC1C2CC3C(=O)OC1C3C2 ; C=C(C)C(=O)NCC(=O)OC1C2CC3C(=O)OC1C3C2 ; C=C(C(=O)NCC(=O)OC1C2CC3C(=O)OC1C3C2)C(F)(F)F]

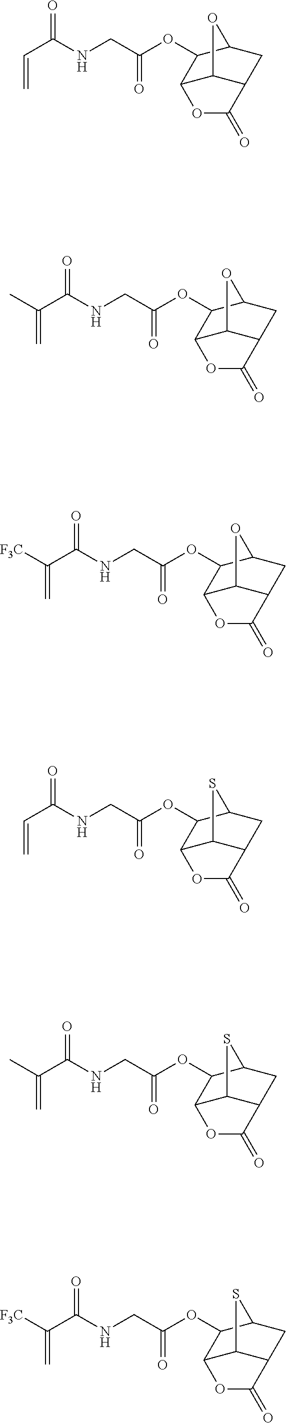 [SMILES: C=CC(=O)NCC(=O)OC1C2CC3C(=O)OC1C3O2 ; C=C(C)C(=O)NCC(=O)OC1C2CC3C(=O)OC1C3O2 ; C=C(C(=O)NCC(=O)OC1C2CC3C(=O)OC1C3O2)C(F)(F)F ; C=CC(=O)NCC(=O)OC1C2CC3C(=O)OC1C3S2 ; C=C(C)C(=O)NCC(=O)OC1C2CC3C(=O)OC1C3S2 ; C=C(C(=O)NCC(=O)OC1C2CC3C(=O)OC1C3S2)C(F)(F)F]

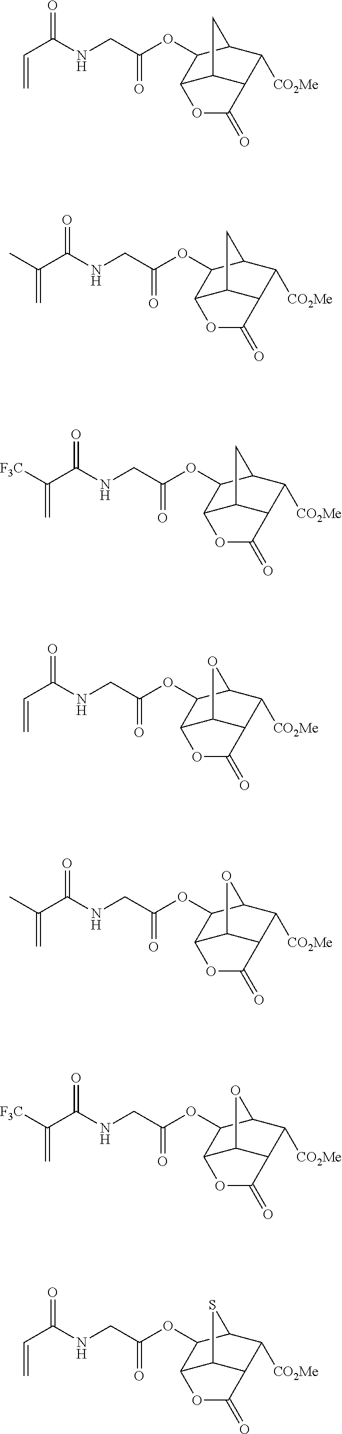

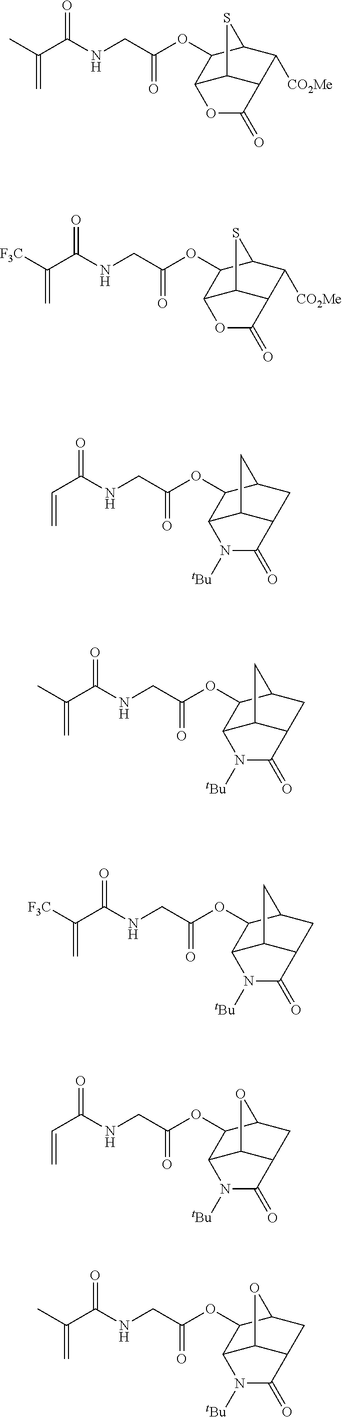

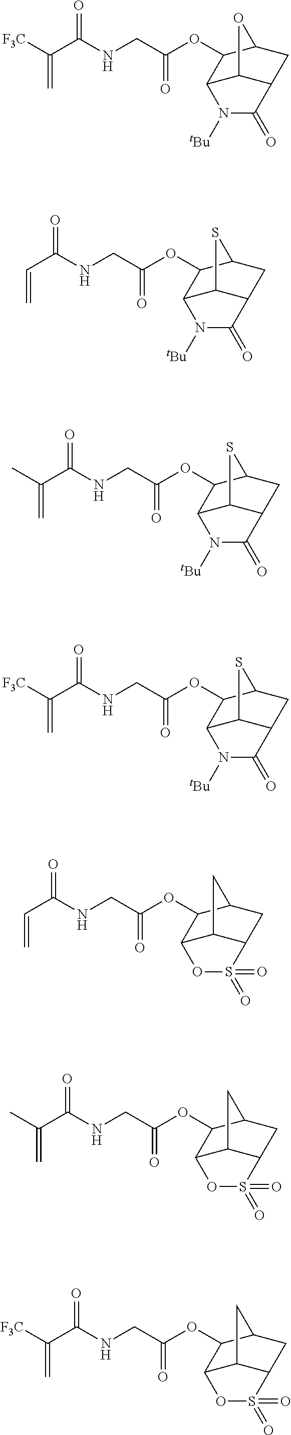

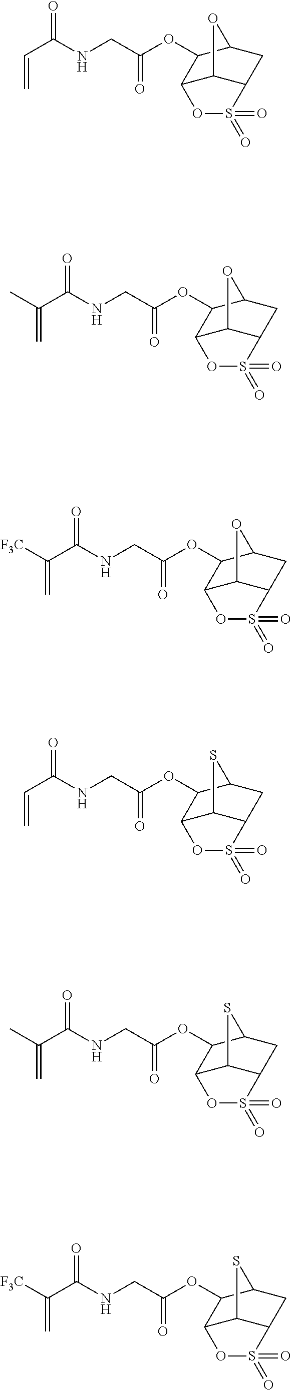 [SMILES: C=CC(=O)NCC(=O)OC1C2CC3C(O2)C1OS3(=O)=O ; C=C(C)C(=O)NCC(=O)OC1C2CC3C(O2)C1OS3(=O)=O ; C=C(C(=O)NCC(=O)OC1C2CC3C(O2)C1OS3(=O)=O)C(F)(F)F ; C=CC(=O)NCC(=O)OC1C2CC3C(S2)C1OS3(=O)=O ; C=C(C)C(=O)NCC(=O)OC1C2CC3C(S2)C1OS3(=O)=O ; C=C(C(=O)NCC(=O)OC1C2CC3C(S2)C1OS3(=O)=O)C(F)(F)F]

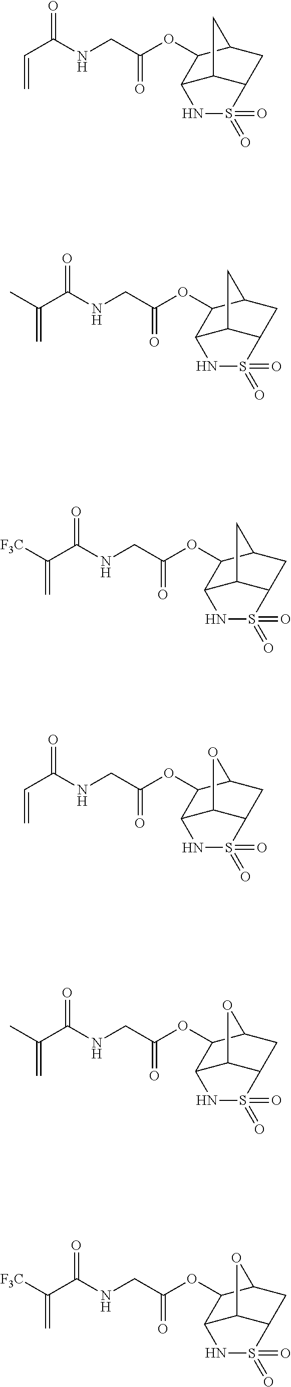 [SMILES: C=CC(=O)NCC(=O)OC1C2CC3C1NS(=O)(=O)C3C2 ; C=C(C)C(=O)NCC(=O)OC1C2CC3C1NS(=O)(=O)C3C2 ; C=C(C(=O)NCC(=O)OC1C2CC3C1NS(=O)(=O)C3C2)C(F)(F)F ; C=CC(=O)NCC(=O)OC1C2CC3C(O2)C1NS3(=O)=O ; C=C(C)C(=O)NCC(=O)OC1C2CC3C(O2)C1NS3(=O)=O ; C=C(C(=O)NCC(=O)OC1C2CC3C(O2)C1NS3(=O)=O)C(F)(F)F]

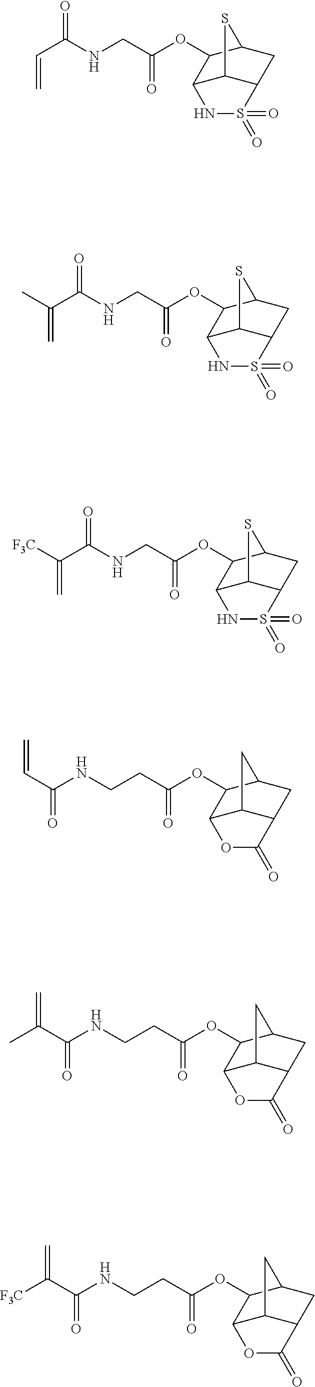 [SMILES: C=CC(=O)NCC(=O)OC1C2CC3C(S2)C1NS3(=O)=O ; C=C(C)C(=O)NCC(=O)OC1C2CC3C(S2)C1NS3(=O)=O ; C=C(C(=O)NCC(=O)OC1C2CC3C(S2)C1NS3(=O)=O)C(F)(F)F ; C=CC(=O)NCCC(=O)OC1C2CC3C(=O)OC1C3C2 ; C=C(C)C(=O)NCCC(=O)OC1C2CC3C(=O)OC1C3C2 ; C=C(C(=O)NCCC(=O)OC1C2CC3C(=O)OC1C3C2)C(F)(F)F]

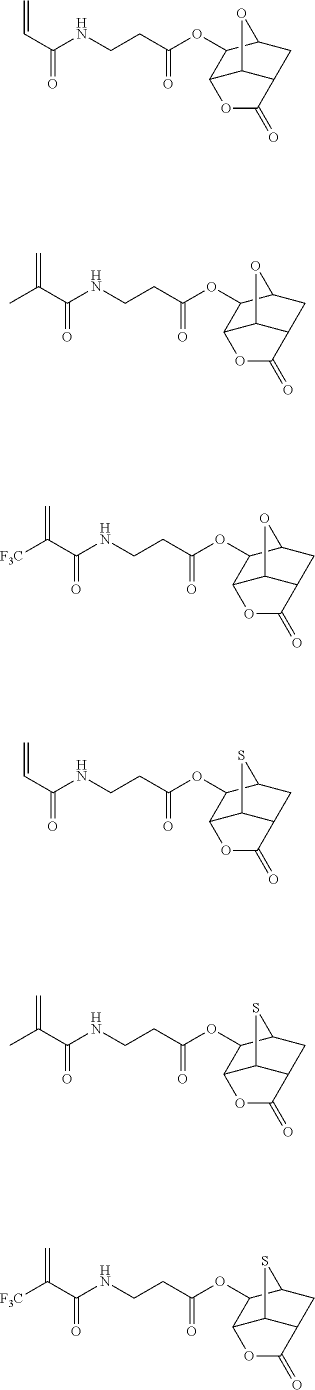 [SMILES: C=CC(=O)NCCC(=O)OC1C2CC3C(=O)OC1C3O2 ; C=C(C)C(=O)NCCC(=O)OC1C2CC3C(=O)OC1C3O2 ; C=C(C(=O)NCCC(=O)OC1C2CC3C(=O)OC1C3O2)C(F)(F)F ; C=CC(=O)NCCC(=O)OC1C2CC3C(=O)OC1C3S2 ; C=C(C)C(=O)NCCC(=O)OC1C2CC3C(=O)OC1C3S2 ; C=C(C(=O)NCCC(=O)OC1C2CC3C(=O)OC1C3S2)C(F)(F)F]

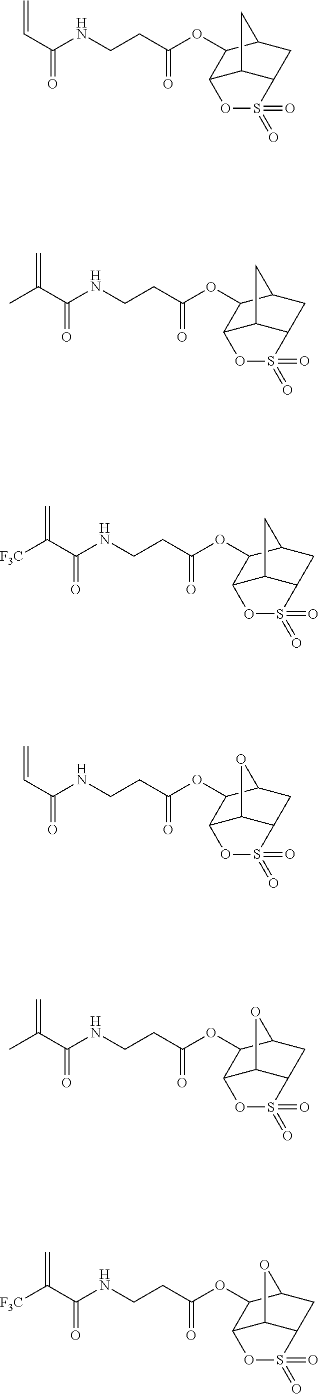 [SMILES: C=CC(=O)NCCC(=O)OC1C2CC3C1OS(=O)(=O)C3C2 ; C=C(C)C(=O)NCCC(=O)OC1C2CC3C1OS(=O)(=O)C3C2 ; C=C(C(=O)NCCC(=O)OC1C2CC3C1OS(=O)(=O)C3C2)C(F)(F)F ; C=CC(=O)NCCC(=O)OC1C2CC3C(O2)C1OS3(=O)=O ; C=C(C)C(=O)NCCC(=O)OC1C2CC3C(O2)C1OS3(=O)=O ; C=C(C(=O)NCCC(=O)OC1C2CC3C(O2)C1OS3(=O)=O)C(F)(F)F]

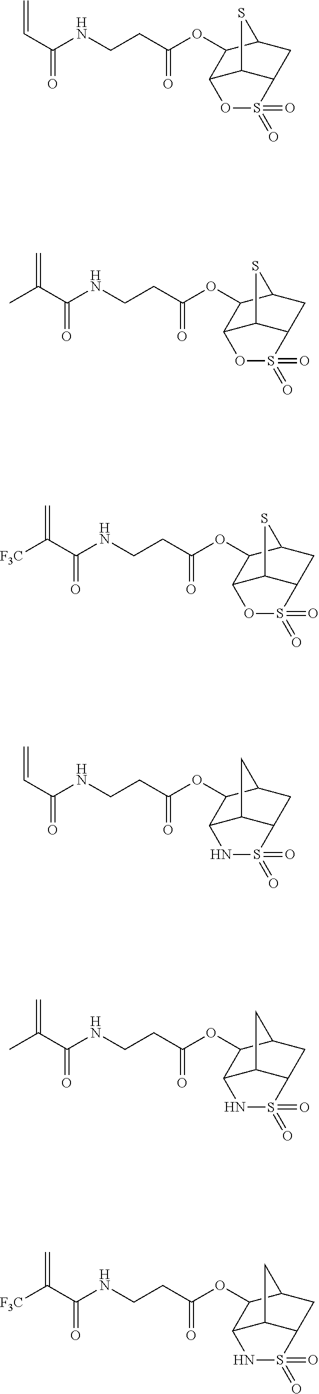 [SMILES: C=CC(=O)NCCC(=O)OC1C2CC3C(S2)C1OS3(=O)=O ; C=C(C)C(=O)NCCC(=O)OC1C2CC3C(S2)C1OS3(=O)=O ; C=C(C(=O)NCCC(=O)OC1C2CC3C(S2)C1OS3(=O)=O)C(F)(F)F ; C=CC(=O)NCCC(=O)OC1C2CC3C1NS(=O)(=O)C3C2 ; C=C(C)C(=O)NCCC(=O)OC1C2CC3C1NS(=O)(=O)C3C2 ; C=C(C(=O)NCCC(=O)OC1C2CC3C1NS(=O)(=O)C3C2)C(F)(F)F]

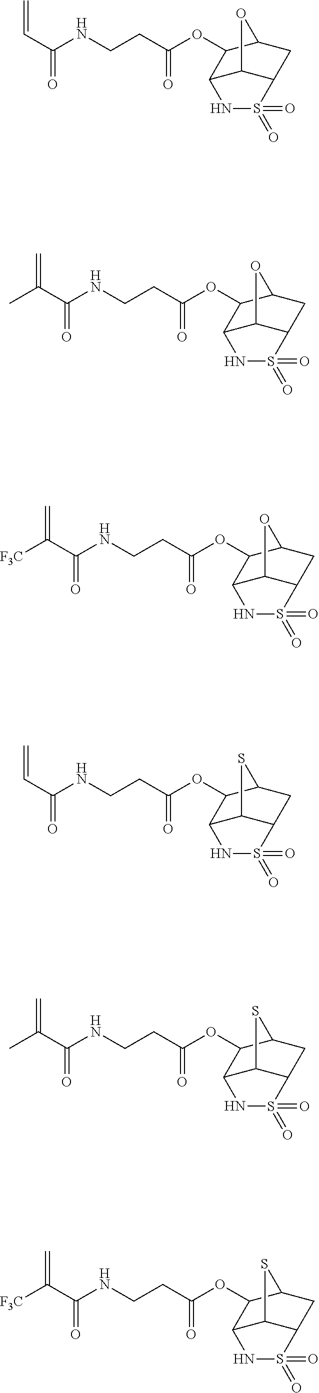 [SMILES: C=CC(=O)NCCC(=O)OC1C2CC3C(O2)C1NS3(=O)=O ; C=C(C)C(=O)NCCC(=O)OC1C2CC3C(O2)C1NS3(=O)=O ; C=C(C(=O)NCCC(=O)OC1C2CC3C(O2)C1NS3(=O)=O)C(F)(F)F ; C=CC(=O)NCCC(=O)OC1C2CC3C(S2)C1NS3(=O)=O ; C=C(C)C(=O)NCCC(=O)OC1C2CC3C(S2)C1NS3(=O)=O ; C=C(C(=O)NCCC(=O)OC1C2CC3C(S2)C1NS3(=O)=O)C(F)(F)F]

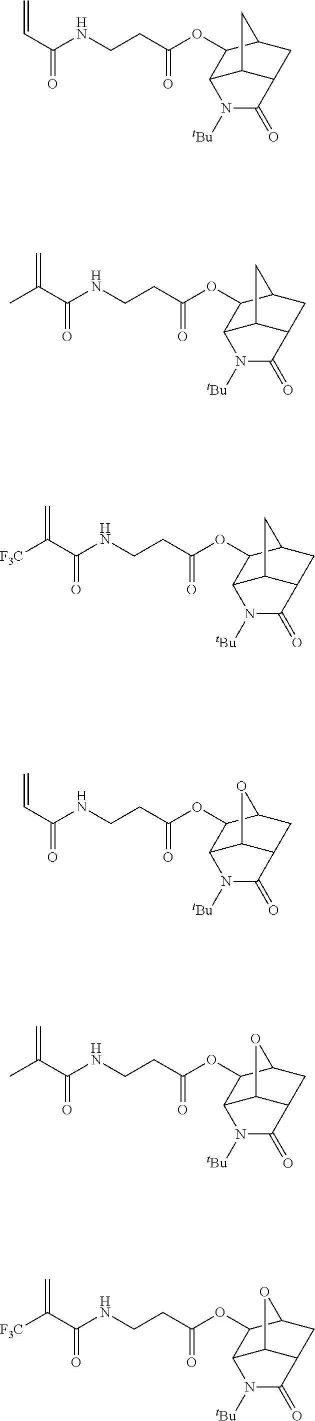 [SMILES: C=CC(=O)NCCC(=O)OC1C2CC3C(=O)N(C(C)(C)C)C1C3C2 ; C=C(C)C(=O)NCCC(=O)OC1C2CC3C(=O)N(C(C)(C)C)C1C3C2 ; C=C(C(=O)NCCC(=O)OC1C2CC3C(=O)N(C(C)(C)C)C1C3C2)C(F)(F)F ; C=CC(=O)NCCC(=O)OC1C2CC3C(=O)N(C(C)(C)C)C1C3O2 ; C=C(C)C(=O)NCCC(=O)OC1C2CC3C(=O)N(C(C)(C)C)C1C3O2 ; C=C(C(=O)NCCC(=O)OC1C2CC3C(=O)N(C(C)(C)C)C1C3O2)C(F)(F)F]

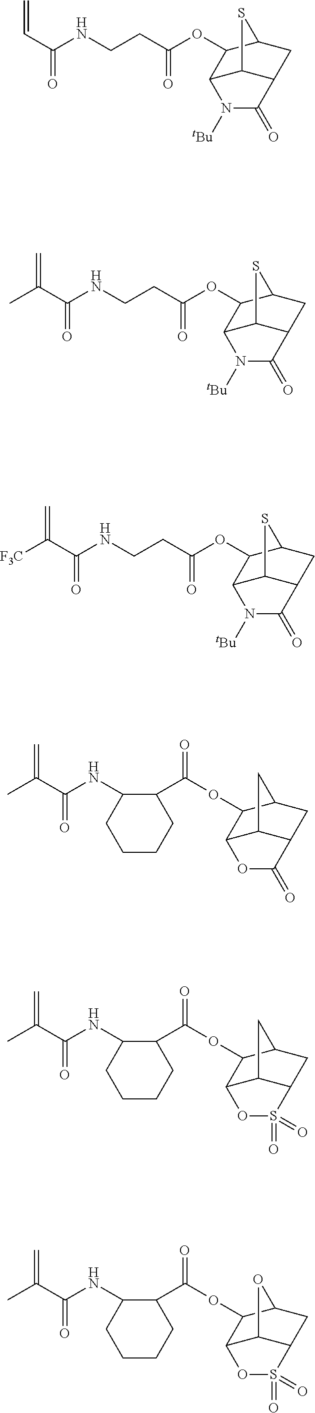 [SMILES: C=CC(=O)NCCC(=O)OC1C2CC3C(=O)N(C(C)(C)C)C1C3S2 ; C=C(C)C(=O)NCCC(=O)OC1C2CC3C(=O)N(C(C)(C)C)C1C3S2 ; C=C(C(=O)NCCC(=O)OC1C2CC3C(=O)N(C(C)(C)C)C1C3S2)C(F)(F)F ; C=C(C)C(=O)NC1CCCCC1C(=O)OC1C2CC3C(=O)OC1C3C2 ; C=C(C)C(=O)NC1CCCCC1C(=O)OC1C2CC3C1OS(=O)(=O)C3C2 ; C=C(C)C(=O)NC1CCCCC1C(=O)OC1C2CC3C(O2)C1OS3(=O)=O]

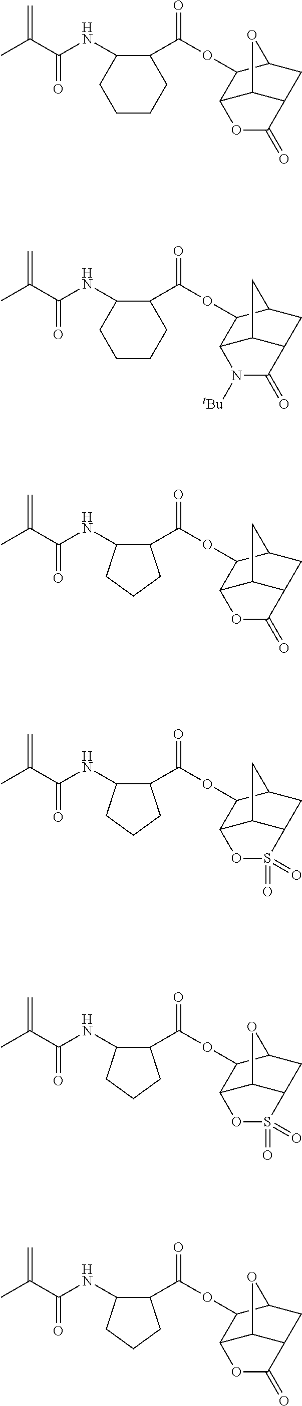 [SMILES: C=C(C)C(=O)NC1CCCCC1C(=O)OC1C2CC3C(=O)OC1C3O2 ; C=C(C)C(=O)NC1CCCCC1C(=O)OC1C2CC3C(=O)N(C(C)(C)C)C1C3C2 ; C=C(C)C(=O)NC1CCCC1C(=O)OC1C2CC3C(=O)OC1C3C2 ; C=C(C)C(=O)NC1CCCC1C(=O)OC1C2CC3C1OS(=O)(=O)C3C2 ; C=C(C)C(=O)NC1CCCC1C(=O)OC1C2CC3C(O2)C1OS3(=O)=O ; C=C(C)C(=O)NC1CCCC1C(=O)OC1C2CC3C(=O)OC1C3O2]

### (Production Method for Acrylamide Derivative (1))

No particular limitation is imposed on the method for producing the acrylamide derivative (1) of the present invention, and, for example, the acrylamide derivative (1) may be produced as described below. Specifically, the acrylamide derivative (1) may be produced by causing a carboxylic acid derivative (hereinafter may be referred to as “carboxylic acid derivative (4)”) to be react with an alcohol derivative (hereinafter may be referred to as “alcohol derivative (5)”).

Hereinafter, the case in which R¹¹ is a hydrogen atom will be described. This reaction may be referred to as “reaction (a)”).

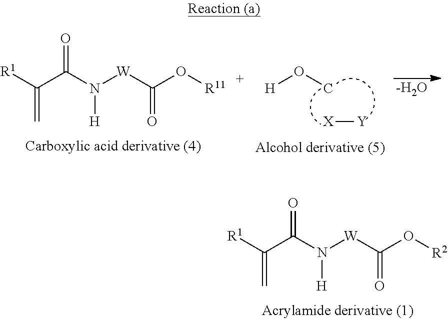

(In the reaction scheme, R¹, R², W, X, and Y, have the same meanings as defined above, and preferred members are the same as described above.)

Examples of the carboxylic acid derivative (4) include N-acryloylglycine, N-methacryloylglycine, N-(2-trifluoromethylacryloyl)glycine, N-acryloyl-3-alanine, and N-methacryloyl-β-alanine. Of these, N-acryloylglycine and N-methacryloylglycine are preferred from the viewpoint of availability.

The amount of carboxylic acid derivative (4) used in the reaction is preferably 0.1 to 5 mol on the basis of 1 mol of the alcohol derivative (5), more preferably 0.8 to 5 mol. The amount is yet more preferably 1 to 3 mol, from the viewpoints of economy and ease of post-treatment.

No particular limitation is imposed on the method of obtaining the alcohol derivative (5). Some members thereof may be readily available through an industrial method. In one possible procedure, the alcohol derivative (5) is produced through forming a norbornene derivative via cycloaddition of a diene compound such as cyclopentadiene or furan to a compound such as acryloyl chloride or vinylsulfonyl chloride, hydrolyzing the norbornene derivative, and oxidizing the hydrolysis product with m-chloroperbenzoic acid or a similar compound.

Among alcohol derivatives (5), alcohol derivatives represented by the following formula (hereinafter referred to as alcohol derivatives (6)):

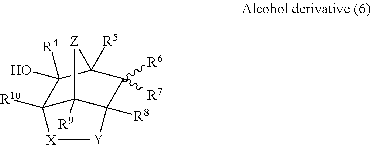

may be produced through several methods. For example, a target product may be produced through subjecting a corresponding diene and a dienophile to Diels-Alder reaction, optionally deriving the adduct to another intermediate, and performing epoxidation. Alternatively, the formed epoxidation compound obtained through epoxidation is treated with a basic substance, to thereby produce a target product.

In a specific case, 5-hydroxy-2,6-norbornane sultone, which is a species of the alcohol derivative (6) in which each of R⁴, R⁵, R⁶, R⁷, R⁸, R⁹, and R¹⁰ is a hydrogen atom, X is —O—, Y is >S(═O)₂, and Z is a methylene group may be produced through the following procedure. Specifically, cyclopentadiene and in situ generated vinylsulfonyl chloride are subjected to Diels-Alder reaction, to thereby form 5-norbornene-2-sulfonyl chloride. The chloride is treated through contact with aqueous sodium hydroxide, to thereby form sodium 5-norbornene-2-sulfonate. The salt is subjected to epoxidation with performic acid. The thus-formed epoxy compound is caused to be reacted with a basic substance such as potassium t-butoxide, to thereby produce a target product (see, for example, Japanese Patent Application Laid-Open (kokai) No. 2010-83873).

Another species of the alcohol derivative (6) in which each of R⁴, R⁵, R⁶, R⁷, R⁸, R⁹, and R¹⁰ is a hydrogen atom, X is >N—R³, R³ is a t-butyl group, Y is >C═O, and Z is a methylene group may be produced through the following procedure. Specifically, cyclopentadiene and acryloyl chloride are subjected to Diels-Alder reaction, and the product is reacted with t-butylamine, to thereby form N-t-butylbicyclo[2.2.1]hept-5-ene-2-carboxamide. The carboxamide is epoxidized through contact with m-chloroperbenzoic acid in the presence of a basic compound such as potassium carbonate, to thereby form N-t-butyl-5,6-epoxybicyclo[2.2.1]hept-2-carboxamide. The thus-obtained epoxy compound is reacted with a basic substance such as potassium t-butoxide, to thereby produce a target product.

Yet another species of the alcohol derivative (6) in which each of R⁴, R⁵, R⁶, R⁷, R⁸, R⁹, and R¹⁰ is a hydrogen atom, X is —O—, Y is >C═O, and Z is a methylene group may be produced through a method disclosed in “H. B. Henbest et al., J. Chem. Soc., p. 221-226 (1959).”

Other alcohol derivatives (5) may be produced with reference to the aforementioned methods, known methods, and Synthesis Examples of the present specification.

Reaction (a) may be carried out in the presence or absence of a catalyst. Examples of the catalyst include mineral acids such as hydrochloric acid and sulfuric acid; organic acids such as methanesulfonic acid, p-toluenesulfonic acid, and trifluoromethanesulfonic acid; and Lewis acids such as boron trifluoride, aluminum trichloride, and dibutyltin dilaurate. Among these catalysts, mineral acids and organic acids are preferred.

Reaction (a) is preferably carried out in the presence of a catalyst, from the viewpoint of reaction rate. A single catalyst may be employed, or two or more catalysts may be employed in combination, so long as an acid is not mixed with a base.

When reaction (a) is carried out in the presence of a catalyst, the amount of the catalyst employed is preferably 0.001 to 5 mol, more preferably 0.005 to 2 mol, yet more preferably 0.005 to 0.5 mol, on the basis of 1 mol of the alcohol derivative (5).

Reaction (a) may be carried out in the presence or absence of a polymerization inhibitor. No particular limitation is imposed on the polymerization inhibitor employed. Examples of the polymerization inhibitor include quinone compounds such as hydroquinone, methoxyphenol, benzoquinone, toluquinone, and p-t-butylcatechol; alkylphenol compounds such as 2,6-di-t-butylphenol, 2,4-di-t-butylphenol, and 2-t-butyl-4,6-dimethylphenol; amine compounds such as phenothiazine; and 2,2,6,6-tetramethylpiperidine-N-oxyl compounds such as 2,2,6,6-tetramethylpiperidine-N-oxyl and 4-acetamido-2,2,6,6-tetramethylpiperidine-N-oxyl. These polymerization inhibitors may be employed singly or in combination of two or more species.

When a polymerization inhibitor is employed, the amount of the polymerization inhibitor is preferably 0.001 to 5 mass %, more preferably 0.001 to 1 mass %, much more preferably 0.005 to 0.5 mass %, on the basis of the mass of the entire reaction mixture, exclusive of the below-described solvent(s).

Reaction (a) may be carried out in the presence or absence of a solvent. No particular limitation is imposed on the solvent employed, so long as it does not inhibit the reaction. Examples of the solvent include saturated hydrocarbons such as hexane, heptane, octane, and cyclohexane; aromatic hydrocarbons such as benzene, toluene, and xylene; halogenated hydrocarbons such as methylene chloride, 1,2-dichloroethane, and chloroform; halogenated aromatic hydrocarbons such as chlorobenzene and fluorobenzene; ethers such as diethyl ether, diisopropyl ether, tetrahydrofuran, 1,4-dioxane, cyclopentyl methyl ether, and 1,2-dimethoxyethane; esters such as methyl acetate, ethyl acetate, and propyl acetate; nitriles such as acetonitrile, propionitrile, and benzonitrile; and amides such as N,N-dimethylformamide, N,N-dimethylacetamide, and N-methylpyrrolidone. These solvents may be employed singly or in combination of two or more species.

When reaction (a) is carried out in the presence of a solvent, the amount of the solvent employed is preferably 0.5 to 100 parts by mass, on the basis of 1 part by mass of the alcohol derivative (5). In order to facilitate post-treatment, the amount is more preferably 0.5 to 20 parts by mass.

The temperature of reaction (a) may vary with, for example, the carboxylic acid derivative (4) and alcohol derivative (5) employed, or the type of an optionally employed catalyst or solvent. The reaction temperature is preferably about −30 to about 120° C., more preferably −10 to 60° C.

No particular limitation is imposed on the reaction pressure, but the reaction is preferably carried out at ambient pressure or lower from the viewpoint of production cost.

The reaction time may vary with, for example, the carboxylic acid derivative (4) and alcohol derivative (5) employed, or the type of an optionally employed catalyst or solvent. The reaction time is preferably about 0.5 hours to about 48 hours, more preferably 1 hour to 24 hours.

No particular limitation is imposed on the operation method of reaction (a). Since the rate of reaction increases by removing by-produced water during reaction, preferably, reaction (a) is performed distilling out water, or reaction (a) is performed in the presence of a dehydrating agent, or the two techniques are employed in combination. No particular limitation is imposed on the dehydrating agent, so long as the agent does not impair the reaction. Examples of the dehydrating agent include inorganic compounds such as sodium sulfate anhydrate and magnesium sulfate anhydrate, and acid anhydrides such as acetic anhydride.

No particular limitation is imposed on the method and order of feeding the reagents into the reaction system. In one embodiment, all of the carboxylic acid derivative (4), the alcohol derivative (5), and the catalyst, solvent, and dehydrating agent, which are optionally employed, are fed into a reactor, and the contents are stirred, to thereby perform reaction (a).

In an alternative method, a compound represented by formula (4) in which R¹¹ is a hydrogen atom is esterified with an esterifying agent, to thereby activate the carboxylic group of the carboxylic acid derivative (4), and the activated species is reacted with the alcohol derivative (5). Hereinafter, the reaction will be referred as “reaction (b).”

Examples of the esterifying agent include carboxyl chlorides such as acetyl chloride, pivaloyl chloride, and 2,4,6-trichlorobenzoyl chloride; sulfonyl chlorides such as methanesulfonyl chloride, p-toluenesulfonyl chloride, and trifluoromethanesulfonyl chloride; carbodiimides such as dicyclohexylcarbodiimide (DCC), diisopropylcarbodiimide (DIC), and 1-ethyl-3-(3-dimethylaminopropyl)carbodiimide hydrochloride; triazoles such as N-hydroxybenzotriazole (HOBt) and 1-hydroxy-7-azabenzotriazole (HOAt); and imides such as N-hydroxysuccinimide (HOSu).

The ester group in formula (4) activated with the esterifying agent has R¹¹ which is —C(═O)R¹², —S(═O)₂R¹³, —C(═NR¹⁴)—NHR¹⁵, or a group represented by the following formula (7):

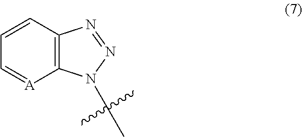

(wherein A represents a carbon atom or a nitrogen atom).

R¹² represents a C1 to C6 alkyl group, a C3 to C6 cycloalkyl group, or a substituted or non-substituted phenyl group. Examples of the C1 to C6 alkyl group include the same as exemplified in relation to R⁴, R⁵, R⁶, R⁸, R⁹, and R¹⁰. Of these, a methyl group and a t-butyl group are preferred. Examples of the C3 to C6 cycloalkyl group include the same as exemplified in relation to R⁴, R⁵, R⁶, R⁸, R⁹, and R¹⁰. Examples of the substituent of the optionally substituted phenyl group represented by R¹² include a C1 to C6 alkyl group; and a halogen atom such as fluorine, chlorine, bromine, or iodine.

R¹³ represents a substituted or non-substituted C1 to C6 alkyl group, or a substituted or non-substituted phenyl group. Examples of the C1 to C6 alkyl group include the same as exemplified in relation to R⁴, R⁵, R⁶, R⁸, R⁹, and R¹⁰. Of these, a methyl group is preferred. Examples of the substituent of the optionally substituted alkyl group represented by R¹³ include a halogen atom such as fluorine, chlorine, bromine, or iodine. Of these, a fluorine atom is preferred. Examples of the substituent of the optionally substituted phenyl group represented by R¹³ include a C1 to C5 alkyl group such as methyl or ethyl. Of these, a methyl group is preferred.

Each of R¹⁴ and R¹⁵ represents a C1 to C10 alkyl group, a C3 to C10 cycloalkyl group, or a dialkylaminoalkyl group. Examples of the C1 to C10 alkyl group include methyl, ethyl, n-propyl, isopropyl, n-butyl, t-butyl, n-hexyl, n-octyl, and n-decyl. Of these, a C1 to C5 alkyl group is preferred, with an isopropyl group being more preferred. Examples of the C3 to C10 cycloalkyl group include cyclopropyl, cyclopentyl, cyclohexyl, cyclooctyl, and cyclodecyl. Of these, a C5 to C8 cycloalkyl group is preferred, with cyclohexyl being more preferred. The dialkylaminoalkyl group is a C1 to C5 (preferably C3) alkyl group having an amino group substituted by two C1 to C5 alkyl groups (preferably methyl groups).

Among the aforementioned members, each of R¹⁴ and R¹⁵ is preferably a C1 to C5 alkyl group or a C5 to C8 cycloalkyl group, with an isopropyl group or a cyclohexyl group being more preferred.

In formula (6), A represents a carbon atom or a nitrogen atom.

No particular limitation is imposed on the conditions where reaction between a carboxylic acid derivative (4) in which R¹¹ is a hydrogen atom and the esterifying agent, and the reaction may be performed under generally known conditions. After completion of the esterification reaction, the esterified carboxylic acid derivative (4) may be used in the reaction with the alcohol derivative (5) as the obtained reaction mixture containing the esterified product without further purification or after purification. From the viewpoints of operational simplicity and production cost, a non-purified product is preferably used.

Reaction (b) may be carried out in the presence or absence of a catalyst. Examples of the catalyst include tertiary amines such as triethylamine, tributylamine, N,N-dimethylaniline, 1,4-diazabicyclo[2.2.2]octane, 1,5-diazabicyclo[4.3.0]non-5-ene, and 1,8-diazabicyclo[5.4.0]undec-7-ene; and nitrogen-containing heterocyclic aromatic compounds such as pyridine, 2-methylpyridine, and 4-(dimethylamino)pyridine. Of these, triethylamine, 1,4-diazabicyclo[2.2.2]octane, and 1,8-diazabicyclo[5.4.0]undec-7-ene are preferred.

Reaction (b) is preferably carried out in the presence of a catalyst, from the viewpoint of reaction rate. A single catalyst may be employed, or two or more catalysts may be employed in combination, so long as an acid is not mixed with a base.

When reaction (b) is carried out in the presence of a catalyst, the amount of the catalyst employed is preferably 0.001 to 5 mol, more preferably 0.005 to 2 mol, yet more preferably 0.1 to 2 mol, on the basis of 1 mol of the alcohol derivative (5).

Reaction (b) may be carried out in the presence or absence of a polymerization inhibitor. Examples of the polymerization inhibitor include those exemplified in relation to the aforementioned reaction (a). These polymerization inhibitors may be employed singly or in combination of two or more species.

When a polymerization inhibitor is employed, the amount of the polymerization inhibitor is preferably 0.001 to 5 mass %, more preferably 0.001 to 1 mass %, much more preferably 0.005 to 0.5 mass %, on the basis of the mass of the entire reaction mixture, exclusive of the below-described solvent(s).

Reaction (b) may be carried out in the presence or absence of a solvent. Examples of the solvent include those exemplified in relation to the aforementioned reaction (a). These solvents may be employed singly or in combination of two or more species.

When reaction (b) is carried out in the presence of a solvent, the amount of the solvent employed is preferably 0.5 to 100 parts by mass on the basis of 1 part by mass of the alcohol derivative (5). In order to facilitate post-treatment, the amount is more preferably 0.5 to 20 parts by mass.

The temperature of reaction (b) may vary with, for example, the carboxylic acid derivative (4) and alcohol derivative (5) employed, or the type of an optionally employed catalyst or solvent. The reaction temperature is preferably about −30 to about 120° C., more preferably −10 to 60° C.

No particular limitation is imposed on the reaction pressure, but the reaction is preferably carried out at ambient pressure for the sake of convenience.

The time of reaction (b) may vary with, for example, the carboxylic acid derivative (4) and alcohol derivative (5) employed, or the type of an optionally employed catalyst or solvent. The reaction time is preferably about 0.5 hours to about 48 hours, more preferably 1 hour to 24 hours.

Reaction (b) is preferably carried out in an atmosphere of an inert gas such as nitrogen or argon, from the viewpoint of the stability of the carboxylic acid derivative (4).

No particular limitation is imposed on the operational method of reaction (b). In one possible procedure, under an inert gas, the carboxylic acid derivative (4), a catalyst, and a solvent are fed to a reactor, and the alcohol derivative (5) and a solvent are added to the mixture.

The reaction (b) may be terminated by adding water to the reaction system. The reaction mixture is subjected to extraction with solvent, and the obtained organic layer is concentrated, to thereby isolate the acrylamide derivative (1)

Separation and purification of an acrylamide derivative (1) from the reaction mixture obtained by the aforementioned reaction (a) or (b) may be carried out through a method which is generally employed for separation and purification of an organic compound.

For example, separation of an acrylamide derivative (1) may be carried out by adding water to the reaction mixture after completion of reaction, subjecting the mixture to extraction with an organic solvent, and concentrating the resultant organic layer. Optionally, purification may be carried out through, for example, recrystallization, distillation, or silica gel column chromatography, to thereby produce an acrylamide derivative (1) of high purity.

Optionally, the metal content of the thus-produced acrylamide derivative (1) may be reduced by adding a chelating agent such as nitrilotriacetic acid or ethylenediaminetetraacetic acid to the derivative, and subjecting the resultant mixture to filtration, or treatment by means of a metal removal filter such as “ZETA PLUS (registered trademark)” (trade name, product of Sumitomo 3M Limited), PROTEGO (trade name, product of Nihon Entegris K.K.), or ION CLEAN (trade name, product of Pall Corporation).

### [Polymer]

A homopolymer of the acrylamide derivative (1) of the present invention or a copolymer of the acrylamide derivative (1) and another polymerizable compound is useful as a polymer for a photoresist composition.

The polymer of the present invention contains a structural unit derived from an acrylamide derivative (1) in an amount of more than 0 mol % to 100 mol %. The amount of the structural unit is preferably 10 to 80 mol %, more preferably to 70 mol %, much more preferably 30 to 70 mol %, for improvement of LWR and resolution.

Specific examples of the polymerizable compound which can be copolymerized with the acrylamide derivative (1) (hereinafter the compound may be referred to as “copolymerizable monomer”) include, but are not particularly limited to, compounds represented by the following chemical formulas.

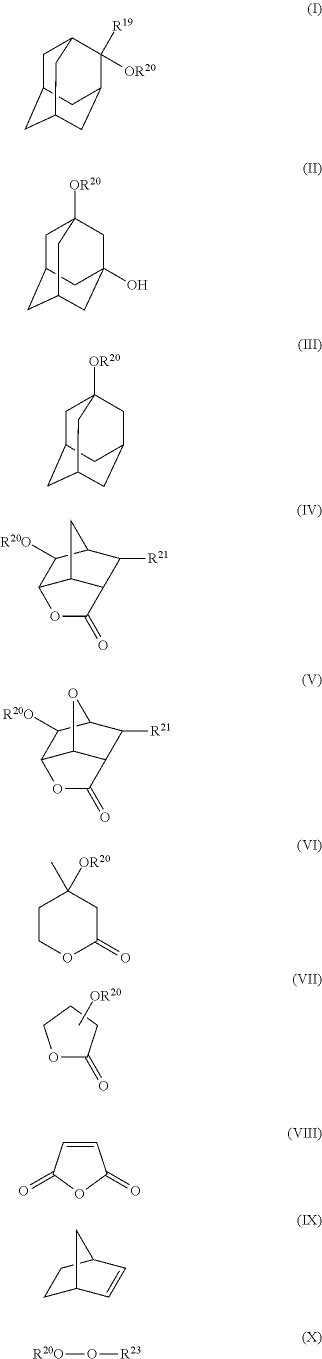

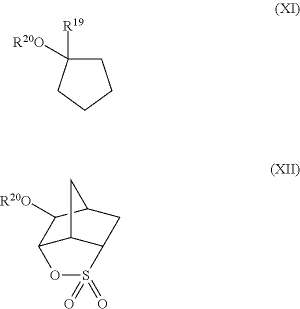

In the aforementioned formulas (I) to (XII), R¹⁹ represents a hydrogen atom or a C1 to C3 alkyl group; R²⁰ represents a polymerizable group; R²¹ represents a hydrogen atom or —COOR²²; R²² represents a C1 to C3 alkyl group; and R²³ represents a C1 to C4 alkyl group.

Examples of the C1 to C3 alkyl group represented by each of R¹⁹ and R²² in the copolymerizable monomer include methyl, ethyl, n-propyl, and isopropyl. Examples of the alkyl group represented by R²³ include methyl, ethyl, n-propyl, isopropyl, n-butyl, isobutyl, s-butyl, and t-butyl. Examples of the polymerizable group represented by R²⁰ include acryloyl, methacryloyl, vinyl, and crotonoyl.

Among the aforementioned copolymerizable monomers, preferred are copolymerizable monomers represented by formulas (I), (II), (IV), (V), (VI), (VII), (XI), and (XII). More preferably, a copolymerizable monomer represented by formula (I) is employed in combination with a copolymerizable monomer represented by formula (II).

### (Production Method for Polymer)

The polymer may be produced through radical polymerization by a customary method. Particularly, a polymer having a small molecular weight distribution is synthesized through, for example, living radical polymerization.

In a general radical polymerization method, optionally one or more acrylamide derivatives (1) and optionally one or more of the aforementioned copolymerizable monomers are polymerized in the presence of a radical polymerization initiator, a solvent, and optionally a chain transfer agent.

No particular limitation is imposed on the method for carrying out radical polymerization, and radical polymerization may be carried out through a conventional method employed for production of an acrylic resin, such as solution polymerization, emulsion polymerization, suspension polymerization, or bulk polymerization.

Examples of the aforementioned radical polymerization initiator include hydroperoxide compounds such as t-butyl hydroperoxide and cumene hydroperoxide; dialkyl peroxide compounds such as di-t-butyl peroxide, t-butyl-α-cumyl peroxide, and di-α-cumyl peroxide; diacyl peroxide compounds such as benzoyl peroxide and diisobutyryl peroxide; and azo compounds such as 2,2′-azobisisobutyronitrile and dimethyl 2,2′-azobisisobutyrate.

The amount of the radical polymerization initiator employed may be appropriately determined in consideration of polymerization conditions, including the type and amount of acrylamide derivative (1), copolymerizable monomer, chain transfer agent, and solvent employed for polymerization reaction, and polymerization temperature. Generally, the amount of the radical polymerization initiator is preferably 0.005 to 0.2 mol, more preferably 0.01 to 0.15 mol, on the basis of 1 mol of all the polymerizable compounds [corresponding to the total amount of an acrylamide derivative (1) and a copolymerizable monomer, the same shall apply hereinafter].

Examples of the aforementioned chain transfer agent include thiol compounds such as dodecanethiol, mercaptoethanol, mercaptopropanol, mercaptoacetic acid, and mercaptopropionic acid. When a chain transfer agent is employed, generally, the amount thereof is preferably 0.005 to 0.2 mol, more preferably 0.01 to 0.15 mol, on the basis of 1 mol of all the polymerizable compounds.

No particular limitation is imposed on the aforementioned solvent, so long as it does not inhibit polymerization reaction. Examples of the solvent include glycol ethers such as propylene glycol monoethyl ether, propylene glycol monomethyl ether acetate, ethylene glycol monomethyl ether, ethylene glycol monomethyl ether acetate, ethylene glycol monomethyl ether propionate, ethylene glycol monobutyl ether, ethylene glycol monobutyl ether acetate, and diethylene glycol dimethyl ether; esters such as ethyl lactate, methyl 3-methoxypropionate, methyl acetate, ethyl acetate, and propyl acetate; ketones such as acetone, methyl ethyl ketone (2-butanone), methyl isopropyl ketone, methyl isobutyl ketone, methyl amyl ketone, cyclopentanone, and cyclohexanone; and ethers such as diethyl ether, diisopropyl ether, dibutyl ether, tetrahydrofuran, and 1,4-dioxane.

Generally, the amount of the solvent employed is preferably 0.5 to 20 parts by mass on the basis of 1 part by mass of all the polymerizable compounds. From the viewpoint of economy, the amount is more preferably 1 to 10 parts by mass.

Generally, the polymerization temperature is preferably to 150° C. The polymerization temperature is more preferably 60 to 120° C., from the viewpoint of the stability of a polymer produced.

The polymerization reaction time may vary with polymerization conditions, including the type and amount of acrylamide derivative (1), copolymerizable monomer, polymerization initiator, and solvent employed, and polymerization reaction temperature. Generally, the polymerization time is preferably 30 minutes to 48 hours, more preferably 1 hour to 24 hours.

Polymerization reaction is preferably carried out in an atmosphere of an inert gas such as nitrogen or argon.

The thus-produced polymer may be isolated through a common process such as reprecipitation. The thus-isolated polymer may be dried through, for example, vacuum drying.

Examples of the solvent employed for the reprecipitation process include aliphatic hydrocarbons such as pentane and hexane; alicyclic hydrocarbons such as cyclohexane; aromatic hydrocarbons such as benzene and xylene; halogenated hydrocarbons such as methylene chloride, chloroform, chlorobenzene, and dichlorobenzene; nitrated hydrocarbons such as nitromethane; nitriles such as acetonitrile and benzonitrile; ethers such as diethyl ether, diisopropyl ether, tetrahydrofuran, and 1,4-dioxane; ketones such as acetone and methyl ethyl ketone; carboxylic acids such as acetic acid; esters such as ethyl acetate and butyl acetate; carbonates such as dimethyl carbonate, diethyl carbonate, and ethylene carbonate; alcohols such as methanol, ethanol, propanol, isopropyl alcohol, and butanol; and water. These solvents may be employed singly or in combination of two or more species.

The amount of the solvent employed for the reprecipitation process may vary with the type of the polymer or solvent. Generally, the amount of the solvent is preferably 0.5 to 100 parts by mass on the basis of 1 part by mass of the polymer. From the viewpoint of economy, the amount is more preferably 1 to 50 parts by mass.

No particular limitation is imposed on the weight average molecular weight (Mw) of the polymer, but the Mw is preferably 500 to 50,000, more preferably 1,000 to 30,000, much more preferably 5,000 to 15,000. When the Mw falls within the above preferred range, the polymer is highly useful as a component of the below-described photoresist composition. The Mw of the polymer is determined through the method described hereinbelow in the Examples.

The molecular weight distribution (Mw/Mn) of the polymer is preferably 3 or less, more preferably 2.5 or less, much more preferably 2 or less, for improvement of LWR and resolution.

### [Photoresist Composition]

The photoresist composition of the present invention is prepared by mixing the aforementioned polymer with a photoacid generator and a solvent, and optionally a basic compound, a surfactant, and an additional additive. The respective components will next be described.

### (Photoacid Generator)

No particular limitation is imposed on the photoacid generator employed, and the photoacid generator may be any known photoacid generator which is generally employed in conventional chemically amplified resists. Examples of the photoacid generator include onium salt photoacid generators such as iodonium salts and sulfonium salts; oxime sulfonate photoacid generators; bisalkyl or bisarylsulfonyldiazomethane photoacid generators; nitrobenzyl sulfonate photoacid generators; iminosulfonate photoacid generators; and disulfone photoacid generators. These photoacid generators may be employed singly or in combination of two or more species. Of these, an onium salt photoacid generator is preferred. More preferred is a fluorine-containing onium salt containing a fluorine-containing alkyl sulfonate ion as an anion, since such an onium salt generates a strong acid.

Specific examples of the aforementioned fluorine-containing onium salt include diphenyliodonium trifluoromethanesulfonate or nonafluorobutanesulfonate; bis(4-tert-butylphenyl)iodonium trifluoromethanesulfonate or nonafluorobutanesulfonate; triphenylsulfonium trifluoromethanesulfonate, heptafluoropropanesulfonate, or nonafluorobutanesulfonate; tri(4-methylphenyl)sulfonium trifluoromethanesulfonate, heptafluoropropanesulfonate, or nonafluorobutanesulfonate; dimethyl(4-hydroxynaphthyl)sulfonium trifluoromethanesulfonate, heptafluoropropanesulfonate, or nonafluorobutanesulfonate; monophenyldimethylsulfonium trifluoromethanesulfonate, heptafluoropropanesulfonate, or nonafluorobutanesulfonate; diphenylmonomethylsulfonium trifluoromethanesulfonate, heptafluoropropanesulfonate, or nonafluorobutanesulfonate; (4-methylphenyl)diphenylsulfonium trifluoromethanesulfonate, heptafluoropropanesulfonate, or nonafluorobutanesulfonate; (4-methoxyphenyl)diphenylsulfonium trifluoromethanesulfonate, heptafluoropropanesulfonate, or nonafluorobutanesulfonate; and tri(4-tert-butyl)phenylsulfonium trifluoromethanesulfonate, heptafluoropropanesulfonate, or nonafluorobutanesulfonate. These onium salts may be employed singly or in combination of two or more species.

Generally, the amount of the photoacid generator incorporated is preferably 0.1 to 30 parts by mass, more preferably 0.5 to 10 parts by mass, on the basis of 100 parts by mass of the aforementioned polymer, in order to secure the sensitivity and developability of the photoresist composition.

### (Solvent)

Examples of the solvent incorporated into the photoresist composition include glycol ethers such as propylene glycol monoethyl ether, propylene glycol monomethyl ether acetate, ethylene glycol monomethyl ether, ethylene glycol monomethyl ether acetate, ethylene glycol monomethyl ether propionate, ethylene glycol monobutyl ether, ethylene glycol monobutyl ether acetate, and diethylene glycol dimethyl ether; esters such as ethyl lactate, methyl 3-methoxypropionate, methyl acetate, ethyl acetate, and propyl acetate; ketones such as acetone, methyl ethyl ketone, methyl isopropyl ketone, methyl isobutyl ketone, methyl amyl ketone, cyclopentanone, and cyclohexanone; and ethers such as diethyl ether, diisopropyl ether, dibutyl ether, tetrahydrofuran, and 1,4-dioxane. These solvents may be employed singly or in combination of two or more species.

Generally, the amount of the solvent incorporated is preferably 1 to 50 parts by mass, more preferably 2 to 25 parts by mass, on the basis of 1 part by mass of the polymer.

### (Basic Compound)

In order to reduce the diffusion rate of an acid in a photoresist film for improvement of resolution, the photoresist composition may optionally contain a basic compound in such an amount that the compound does not impair the properties of the photoresist composition. Examples of the basic compound include amides such as formamide, N-methylformamide, N,N-dimethylformamide, acetamide, N-methylacetamide, N,N-dimethylacetamide, N-(1-adamantyl)acetamide, benzamide, N-acetylethanolamine, 1-acetyl-3-methylpiperidine, pyrrolidone, N-methylpyrrolidone, ε-caprolactam, δ-valerolactam, 2-pyrrolidinone, acrylamide, methacrylamide, t-butylacrylamide, methylenebisacrylamide, methylenebismethacrylamide, N-methylolacrylamide, N-methoxyacrylamide, and diacetoneacrylamide; and amines such as pyridine, 2-methylpyridine, 4-methylpyridine, nicotine, quinoline, acridine, imidazole, 4-methylimidazole, benzimidazole, pyradine, pyrazole, pyrrolidine, N-t-butoxycarbonylpyrrolidine, piperidine, tetrazole, morpholine, 4-methylmorpholine, piperazine, 1,4-diazabicyclo[2.2.2]octane, tributylamine, tripentylamine, trihexylamine, triheptylamine, trioctylamine, and triethanolamine. These basic compounds may be employed singly or in combination of two or more species.

When a basic compound is incorporated, generally, the amount thereof—which may vary with the type of the basic compound—is preferably 0.01 to 10 mol, more preferably 0.05 to 1 mol, on the basis of 1 mol of the photoacid generator.

### (Surfactant)

For improvement of coating properties, the photoresist composition may optionally contain a surfactant in such an amount that the surfactant does not impair the properties of the photoresist composition.

Examples of the surfactant include polyoxyethylene lauryl ether, polyoxyethylene stearyl ether, polyoxyethylene oleyl ether, and polyoxyethylene n-octyl phenyl ether. These surfactants may be employed singly or in combination of two or more species.

When a surfactant is incorporated, generally, the amount thereof is preferably 2 parts by mass or less on the basis of 100 parts by mass of the polymer.

### (Additional Additive)

The photoresist composition may also contain an additional additive such as a sensitizer, a halation-preventing agent, a shape-improving agent, a storage stabilizer, or an antifoaming agent in such an amount that the additive does not impair the properties of the photoresist composition.

### (Photoresist Pattern Formation Method)

A specific resist pattern may be formed through the following procedure: the photoresist composition is coated onto a substrate; the composition-coated substrate is generally prebaked at preferably 70 to 160° C. for 1 to 10 minutes; the resultant product is irradiated with a radiation (exposed to light) via a specific mask; subsequently, post-exposure baking is carried out at preferably 70 to 160° C. for 1 to 5 minutes, to thereby form a latent image pattern; and then development is carried out by use of a developer.

Light exposure may be carried out by means of a radiation of any wavelength; for example, UV rays or X-rays. For the case of a semiconductor resist, g-ray, i-ray, or an excimer laser such as XeCl, KrF, KrCl, ArF, or ArCl is generally employed. Of these, ArF excimer laser is preferably employed, for improvement of micropatterning.

The amount of exposure light is preferably 0.1 to 1,000 mJ/cm², more preferably 1 to 500 mJ/cm².

Examples of the developer include alkaline aqueous solutions prepared by dissolving, in water, inorganic bases such as sodium hydroxide, potassium hydroxide, sodium carbonate, and aqueous ammonia; alkylamines such as ethylamine, diethylamine, and triethylamine; alcoholamines such as dimethylethanolamine and triethanolamine; and quaternary ammonium salts such as tetramethylammonium hydroxide and tetraethylammonium hydroxide. Of these, an alkaline aqueous solution prepared by dissolving, in water, a quaternary ammonium salt such as tetramethylammonium hydroxide or tetraethylammonium hydroxide is preferably employed.

Generally, the developer concentration is 0.1 to 20 mass %, more preferably 0.1 to 10 mass %.

### EXAMPLES

The present invention will next be described in detail by way of Examples, which should not be construed as limiting the invention thereto. Measurement of Mw and Mn and calculation of molecular weight distribution factor were carried out as described below.

### (Measurement of Mw and Mn, and Calculation of Molecular Weight Distribution)

For measurement of weight average molecular weight (Mw) and number average molecular weight (Mn), gel permeation chromatography (GPC) employing a differential refractometer as a detector and tetrahydrofuran (THF) as an eluent was carried out under the below-described conditions, and a calibration curve prepared by use of standard polystyrene was employed for molecular weight conversion. Molecular weight distribution (Mw/Mn) was determined by dividing weight average molecular weight (Mw) by number average molecular weight (Mn).

By means of a column prepared by connecting “TSK-gel SUPER HZM-H” (trade name, product of Tosoh Corporation, 4.6 mm×150 mm)×2 and “TSK-gel SUPER HZ2000” (trade name, product of Tosoh Corporation, 4.6 mm×150 mm)×1 in series, GPC measurement was carried out under the following conditions: column temperature: 40° C., differential refractometer temperature: 40° C., and eluent flow rate: 0.35 mL/minute.

### Synthesis Example 1

### Synthesis of 5-hydroxy-2,6-norbornane sultone

To a four-necked flask having a capacity of 1 L and equipped with a stirrer, a thermometer, and a dropping funnel, 0.40 g of phenothiazine, 1154.0 g of tetrahydrofuran THF), and 87.0 g (1.32 mol) of cyclopentadiene were added, and the resultant mixture was cooled to 5° C. or lower under stirring. Subsequently, 195.7 g (1.20 mol) of 2-chloroethanesulfonyl chloride and 146.0 g (1.45 mol) of triethylamine were respectively added to separate dropping funnels, and they were simultaneously added dropwise to the flask at an internal temperature of 5 to 10° C. over 3 hours.

After completion of the addition, the resultant reaction mixture was stirred at 5 to 10° C. for 3 hours, and then the thus-precipitated salt was separated through filtration under reduced pressure, followed by addition of 600.0 g of tetrahydrofuran (THF) to the salt separated through filtration, to thereby obtain 1632.8 g of a filtrate (hereinafter the filtrate will be referred to as “filtrate (A)”). The filtrate (A) was analyzed through gas chromatography. As a result, the filtrate was found to contain 178.2 g (0.925 mol) of 5-norbornene-2-sulfonyl chloride (yield with respect to 2-chloroethanesulfonyl chloride: 77.1%).

To a three-necked flask having a capacity of 3 L and equipped with a stirrer and a thermometer, 920 g of water was added, and the flask was cooled to 20° C. or lower. Under stirring, 80.30 g (2.01 mol) of sodium hydroxide was added to the flask so that the internal temperature was maintained at 20° C. or lower. 1300 g Of “filtrate (A)” (5-norbornene-2-sulfonyl chloride: 141.9 g (0.737 mol)) was added dropwise to the flask at an internal temperature of 20 to 25° C. over 4 hours.

One hour after completion of the addition, the resultant reaction mixture was analyzed through gas chromatography. As a result, 5-norbornene-2-sulfonyl chloride was found to completely disappear. The reaction mixture was concentrated under reduced pressure, to thereby remove THF. Thereafter, the resultant concentrate was transferred to a 2 L separating funnel and washed thrice with 300 g of toluene, to thereby obtain 1065.3 g of an aqueous solution containing 5-norbornene-2-sulfonic acid sodium salt (hereinafter the aqueous solution will be referred to as “aqueous solution (A)”).

“Aqueous solution (A)” was completely added to a three-necked flask having a capacity of 3 L and equipped with a stirrer and a thermometer, and the flask was cooled to 10° C. 93.27 g (2.01 mol) Of 99% formic acid was added dropwise to the flask at an internal temperature of 11 to 15° C., and then the flask was heated so as to attain an internal temperature of 50 to 53° C. Thereafter, 162.50 g (1.43 mol) of 30% aqueous hydrogen peroxide was added dropwise to the flask over three hours. After completion of the addition, the internal temperature was further maintained at 50° C. or thereabout. Seventeen hours after completion of the addition, the resultant reaction mixture was analyzed through high-performance liquid chromatography (HPLC). As a result, the conversion of 5-norbornene-2-sulfonic acid was found to be 98.7%.

The reaction mixture was cooled to 15° C. Then, 36.55 g (0.29 mol) of sodium sulfite was slowly added to the flask at an internal temperature of 15 to 18° C., and no detection of hydrogen peroxide was confirmed by means of starch paper. Subsequently, 140.95 g (1.68 mol) of sodium hydrogencarbonate was slowly added to the flask at an internal temperature of to 17° C., to thereby adjust the pH of the reaction mixture to 7.3. The reaction mixture was subjected to extraction twice with 900 g of ethyl acetate, and the resultant organic layers were combined and concentrated under reduced pressure, to thereby obtain 69.15 g of a yellow-white solid.

The solid was dissolved in 140 g of ethyl acetate at 50° C., the resultant solution was slowly cooled to 10° C., and the thus-precipitated crystals were separated through filtration. The crystals separated through filtration were washed with 30 g of ethyl acetate at 5° C., and then dried under reduced pressure at 40° C. for two hours, to thereby obtain 53.9 g (purity: 99.1%, 0.28 mol) of 5-hydroxy-2,6-norbornane sultone having the following structure (yield with respect to 5-norbornene-2-sulfonyl chloride: 38.1%).

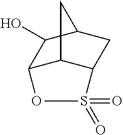 [SMILES: O=S1(=O)OC2C(O)C3CC2C1C3]

¹H-NMR (400 MHz, CDCl₃, TMS, ppm): 1.72 (1H, dd, J=11.6, 1.6 Hz), 2.06-2.10 (3H, m), 2.22 (1H, dd, J=11.2, 1.6 Hz), 2.44 (1H, m), 3.44 (1H, m), 3.50-3.53 (1H, m), 3.93 (1H, brs), 4.61 (1H, d, J=4.8 Hz)

### Synthesis Example 2

### Synthesis of 5-hydroxy-2,6-norbornane carbolactone

To a four-necked flask having a capacity of 1 L and equipped with a stirrer, a thermometer, and a dropping funnel, 0.40 g of p-methoxyphenol, 108.1 g (1.50 mol) of acrylic acid, and 300 mL of toluene were added. 109.1 g (1.65 mol) Of cyclopentadiene was added dropwise to the flask under stirring through the dropping funnel at 40° C. or lower over 2 hours. After completion of the addition, the mixture was continuously stirred at room temperature for 10 hours and then concentrated under reduced pressure, to thereby obtain 167.3 g (1.21 mol) of 5-norbornene-2-carboxylic acid.

The entire amount of the thus-produced 5-norbornene-2-carboxylic acid and 94.6 g (1.81 mol) of 88% formic acid were added to a four-necked flask having a capacity of 1 L and equipped with a stirrer, a thermometer, and a dropping funnel. The two components were mixed at 20 to 30° C. and heated to an internal temperature of the flask of 48 to 50° C. To the mixture, 162.5 g (1.43 mol) of 30% aqueous hydrogen peroxide was added dropwise over 6 hours. After completion of the addition, the mixture was stirred for 10 hours, while the internal temperature was maintained at about 50° C. The reaction mixture was cooled to 15° C. Then, 30.5 g of sodium sulfite was added to the flask at an internal temperature of to 20° C., and no detection of hydrogen peroxide was confirmed by means of starch paper. Subsequently, the pH of the reaction mixture was adjusted to 7.5 with 20% aqueous sodium hydroxide. The reaction mixture was subjected to extraction thrice with 400 g of ethyl acetate, and the resultant organic layers were combined and concentrated under reduced pressure. To the thus-obtained solid, 150 g of ethyl acetate and 750 g of toluene were added, and the mixture was heated, to thereby completely dissolve the solid. The resultant solution was slowly cooled to 0° C., and the thus-precipitated crystals were separated through filtration. The crystals separated through filtration were washed with 200 g of toluene at 5° C., and then dried under reduced pressure at 40° C. for 2 hours, to thereby obtain 117.9 g (purity: 99.3%, 0.76 mol) of 5-hydroxy-2,6-norbornane carbolactone having the following structure.

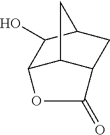 [SMILES: O=C1OC2C(O)C3CC1C2C3]

### Synthesis Example 3

### Synthesis of 5-hydroxy-2,6-(7-oxanorbornane) carbolactone

To a four-necked flask having a capacity of 100 mL and equipped with a stirrer and a thermometer, 48.0 g (0.705 mol) of furan and 20.0 g (0.232 mol) of methyl acrylate were added, and the mixture was cooled to −20° C. To the cooled mixture, 3.0 mL of boron trifluoride-diethyl ether complex was added dropwise, while the internal temperature was maintained at −15 to −18° C. After completion of the addition, the mixture was continuously stirred for 14 hours at an internal temperature of the flask of 0 to 5° C. The reaction mixture was concentrated under reduced pressure, and the concentrate was dissolved in 300 g of ethyl acetate. The solution was washed sequentially with 50 g of water, 50 g of saturated aqueous sodium hydrogencarbonate, and 50 g of saturated brine, and the solution was concentrated under reduced pressure, to thereby obtain 28.3 g of an oily product.

To the oily product, 93.6 g (0.234 mol) of 10% aqueous sodium hydroxide was added, and the mixture was stirred at room temperature for 24 hours. The pH of the mixture was adjusted to 2.0 with concentrate hydrochloric acid. The mixture was subjected to extraction thrice with 300 g of ethyl acetate. The extraction layers were combined and concentrated under reduced pressure, to thereby obtain 21.5 g of solid.

The entire amount of the thus-obtained solid and 12.0 g (0.232 mol) of 88% formic acid were added to a four-necked flask having a capacity of 200 mL and equipped with a stirrer, a thermometer, and a dropping funnel. The two components were mixed at 20 to 30° C. and heated to an internal temperature of the flask of 45 to 46° C. To the mixture, 26.1 g (0.232 mol) of 30% aqueous hydrogen peroxide was added dropwise over 6 hours. After completion of the addition, the mixture was stirred for 20 hours, while the internal was maintained at about 45° C. The reaction mixture was cooled to 15° C. Then, 9.7 g of sodium sulfite was added to the flask at an internal temperature of 15 to 20° C., and no detection of hydrogen peroxide was confirmed by means of starch paper. Subsequently, the pH of the reaction mixture was adjusted to 7.8 with 20% aqueous sodium hydroxide. The reaction mixture was subjected to extraction thrice with 400 g of ethyl acetate, and the resultant organic layers were combined and concentrated under reduced pressure. To the thus-obtained solid, 30 g of ethanol was added, and the mixture was heated, to thereby completely dissolve the solid. The resultant solution was slowly cooled to 0° C., and the thus-precipitated crystals were separated through filtration. The crystals separated through filtration were washed with 10 g of ethanol at 0° C., and then dried under reduced pressure at 40° C. for 2 hours, to thereby obtain 10.8 g (purity: 98.9%, 0.068 mol) of 5-hydroxy-2,6-(7-oxanorbornane) carbolactone having the following structure.

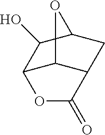 [SMILES: O=C1OC2C(O)C3CC1C2O3]

### Synthesis Example 4

### Synthesis of 5-hydroxy-7-oxanorbornane-2,6-sultone

Methyl vinylsulfonate, serving as a raw material, was synthesized in accordance with a synthesis example disclosed in Angew. Chem., 77(7), 291-302 (1965). Specifically, under nitrogen atmosphere, 326.0 g (2.00 mol) of 2-chloroethanesulfonyl chloride was added to a four-necked flask having a capacity of 2 L and equipped with a stirrer, a thermometer, a dropping funnel, and a three-way cock, and the flask was cooled on an ice bath. Then, 25 wt % sodium methoxide (methanol solution) was added dropwise to the flask while the internal temperature of the flask was adjusted to 2 to 5° C. After completion of the addition, the ice bath was removed, and the contents of the flask were stirred at room temperature for 1 hour. The reaction mixture was filtered, and the filtrate was concentrated under reduced pressure. The concentrate was subjected to simple distillation, to thereby obtain 197.2 g (purity: 97.3%, 1.571 mol) of methyl vinylsulfonate (yield with respect to 2-chloroethanesulfonyl chloride: 78.5%).

Then, 5-hydroxy-7-oxanorbornane-2,6-sultone was synthesized in accordance with Example 2 disclosed in Japanese Patent Application Laid-Open (kokai) No. 2007-31355. Specifically, 150 g (2.20 mol) of furan and 15.0 g of zinc iodide were added to a four-necked flask having a capacity of 300 mL and equipped with a stirrer, a dropping funnel, and a thermometer, and 41.5 g (0.34 mol) of methyl vinylsulfonate was added through the dropping funnel to the mixture at 25 to 27° C. While the temperature was maintained, the contents were continuously stirred for 2 days. The reaction mixture was transferred to a separating funnel having a capacity of 1 L and washed twice with 300 mL of water. Unreacted furan was removed through distillation under reduced pressure, to thereby obtain 22.0 g of methyl 7-oxabicyclo[2.2.1]hept-2-ene-5-sulfonate.

To a four-necked flask having a capacity of 1000 mL and equipped with a stirrer, a dropping funnel, and a thermometer, 22.0 g of methyl 7-oxabicyclo[2.2.1]hept-2-ene-5-sulfonate and 450 g of methylene chloride were sequentially added, and the mixture was cooled to 4° C. Under stirring, 22.9 g (0.17 mol) of m-chloroperbenzoic acid was slowly added so as to maintain the temperature at 10° C. or lower. The contents were stirred at 5 to 7° C. for 4 hours, and 100 g of saturated aqueous sodium sulfite was added thereto, followed by stirring for 30 minutes. The reaction mixture was allowed to stand for phase separation, and the organic layer was washed thrice with 100 g of saturated aqueous sodium hydrogencarbonate. The thus-obtained organic layer was concentrated under reduced pressure, to thereby obtain 20.2 g of methyl 2,3-epoxy-7-oxabicyclo[2.2.1]hept-2-ene-5-sulfonate.

To a four-necked flask having a capacity of 300 mL and equipped with a stirrer, a dropping funnel, and a thermometer, 5.0 (mol/L) of aqueous sodium hydroxide was added. Through the dropping funnel, 29.5 g of methyl 2,3-epoxy-7-oxabicyclo[2.2.1]hept-2-ene-5-sulfonate at an internal temperature of the flask of 20 to 23° C. After completion of the addition, the contents were stirred for 4 hours. The pH of the mixture was adjusted to 7.3 with concentrate hydrochloric acid, while the mixture was cooled with ice water. The mixture was subjected four times to extraction with 300 mL of ethyl acetate. The obtained organic layers were combined and concentrated, and the concentrate was subjected to separation/purification through silica gel column chromatography, to thereby obtain 4.75 g (purity: 98.8%, 0.024 mol) of 5-hydroxy-7-oxanorbornane-2,6-sultone having the following structure.

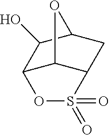 [SMILES: O=S1(=O)OC2C(O)C3CC1C2O3]

### Example 1-(a)

### Synthesis of 2,6-norbornane sultone-5-yl (2-methacryloylaminomethyl)carboxylate (Reaction (a))

To a four-necked flask having a capacity of 5 L and equipped with a thermometer, a stirrer, a Dean-Stark distillation apparatus, and a pressure-controlling device, 231.8 g (1.219 mol) of 5-hydroxy-2,6-norbornane sultone obtained in Synthesis Example 1, 394.4 g (2.074 mol) of p-toluenesulfonic acid monohydrate, 191.7 g (1.338 mol) of N-methacryloylglycine, 2.79 g (0.0225 mol) of p-methoxyphenol, and 2038 g of toluene were added. The contents were allowed to react at an internal temperature of 80 to 83° C. and a pressure of 250 to 260 torr, while 54.95 g of water formed in the reaction was removed through the Dean-Stark distillation apparatus. Thereafter, the reaction was cooled to room temperature, to thereby form two separate layers. The upper layer was removed, and 2041 g of 2-butanone was added to the lower layer at room temperature. Then, 10 mass % aqueous sodium hydroxide was added dropwise thereto under stirring. After completion of the addition, the pH of the reaction mixture was found to be 7.99.

The reaction was allowed to stand for phase separation, and the organic layer was taken. The remaining aqueous layer was re-extracted twice with 2000 g of 2-butanone. The thus-obtained organic layers were washed four times with 1000 g of ion-exchange water, and the washed combined organic layer was concentrated under reduced pressure. Subsequently, diisopropyl ether was added to the concentrate for recrystallization, to thereby obtain 249.0 g (0.790 mol, white solid) of 2,6-norbornane sultone-5-yl (2-methacryloylaminomethyl)carboxylate (yield with respect to 5-hydroxy-2,6-norbornane sultone: 64.8%).

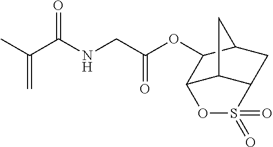 [SMILES: C=C(C)C(=O)NCC(=O)OC1C2CC3C1OS(=O)(=O)C3C2]

¹H-NMR (400 MHz, CDCl₃, TMS, ppm): 1.79 (1H, dd, J=17.2, 1.6 Hz), 1.98 (3H, s), 2.07 (1H, d, J=12.0 Hz), 2.12-2.20 (2H, m), 2.61 (1H, m), 3.48-3.52 (1H, m), 3.56-3.58 (1H, m), 4.05 (1H, dd, J=18.4, 5.2 Hz), 4.12 (1H, dd, J=18.4, 5.6 Hz), 4.74 (1H, d, J=4.8 Hz), 4.79 (1H, d, J=1.6 Hz), 5.41 (1H, m), 5.77 (1H, m), 6.42 (1H, br)

### Example 1-(b)

### Synthesis of 2,6-norbornane sultone-5-yl (2-methacryloylaminomethyl)carboxylate (Reaction (b))

To a four-necked flask having a capacity of 10 L and equipped with a thermometer, a stirrer, a nitrogen conduit, and a dropping funnel, 143.1 g (1.00 mol) of N-methacryloylglycine, 106.1 g (1.05 mol) of triethylamine, 1288 g of tetrahydrofuran (THF), and 0.77 g (3.85 mol) of thiodiphenyleneamine were added. Then, 140.2 g (1.09 mol) of pivaloyl chloride was added dropwise to the flask through the dropping funnel so as to maintain the internal temperature at 10° C. or lower. After completion of the addition, a mixture of 190.2 g (1.00 mol) of 5-hydroxy-2,6-norbornane sultone, 2.44 g (0.02 mol) of 4-dimethylaminopyridine, and 760.9 g of tetrahydrofuran (THF) was added dropwise thereto through the dropping funnel, while the addition rate was controlled so as to maintain the internal temperature at 10° C. or lower. After completion of the addition, 5700 g of ethyl acetate was added, and then 10 mass % aqueous hydrochloric acid was added, to thereby adjust the pH of the reaction mixture to 4 to 5. The reaction mixture was stirred for 30 minutes and allowed to stand for 30 minutes to form two layers. The lower layer (aqueous layer) was removed. The upper layer (organic layer) was washed with 5 mass % aqueous sodium hydrogencarbonate and ion-exchange water, and the washed organic layer was concentrated and cooled for recrystallization, to thereby obtain 126.1 g (0.400 mol, white solid) of 2,6-norbornane sultone-5-yl (2-methacryloylaminomethyl)carboxylate (yield with respect to 5-hydroxy-2,6-norbornane sultone: 40%).

### Example 2

### Synthesis of 2,6-norbornane carbolactone-5-yl (2-methacryloylaminomethyl)carboxylate

The procedure of Example 1-(a) was repeated, except that 231.8 g (1.219 mol) of 5-hydroxy-2,6-norbornane sultone was changed to 188.1 g (1.220 mmol) of 5-hydroxy-2,6-norbornane carbolactone, to thereby obtain 202.1 g (0.723 mmol, white solid) of 2,6-norbornane carbolactone-5-yl (2-methacryloylaminomethyl)carboxylate (yield with respect to 5-hydroxy-2,6-norbornane carbolactone: 59.3%).

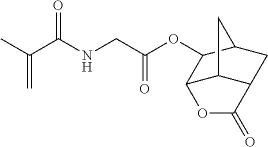 [SMILES: C=C(C)C(=O)NCC(=O)OC1C2CC3C(=O)OC1C3C2]

¹H-NMR (400 MHz, CDCl₃, TMS, ppm): 1.66 (1H, dd, J=12.0, 1.2 Hz), 1.99 (3H, s), 2.01-2.11 (2H, m), 2.54-2.59 (1H, m), 3.21-3.23 (1H, m), 4.08 (1H, dd, J=18.4, 5.6 Hz), 4.10 (1H, dd, J=18.4, 5.6 Hz), 4.56 (1H, d, J=4.8 Hz), 4.66 (1H, m), 5.41 (1H, m), 5.78 (1H, m), 6.41 (1H, br)

### Example 3

### Synthesis of 2,6-(7-oxanorbornane) carbolactone-5-yl (2-methacryloylaminomethyl)carboxylate

The procedure of Example 1-(a) was repeated, except that 231.8 g (1.219 mol) of 5-hydroxy-2,6-norbornane sultone was changed to 192.1 g (1.230 mmol) of 5-hydroxy-2,6-(7-oxanorbornane) carbolactone, to thereby obtain 172.4 g (0.613 mmol, white solid) of 2,6-(7-oxanorbornane) carbolactone-5-yl (2-methacryloylaminomethyl)carboxylate (yield with respect to 5-hydroxy-2,6-(7-oxanorbornane) carbolactone: 49.8%).

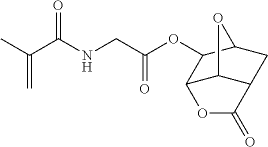 [SMILES: C=C(C)C(=O)NCC(=O)OC1C2CC3C(=O)OC1C3O2]

¹H-NMR (400 MHz, CDCl₃, TMS, ppm): 1.99 (3H, s), 2.09 (1H, dd, J=14.0, 2.0 Hz), 2.23-2.31 (1H, m), 2.74-2.68 (1H, m), 4.10 (1H, dd, J=18.4, 5.6 Hz), 4.14 (1H, dd, J=18.4, 5.6 Hz), 4.67 (1H, d, J=4.8 Hz), 4.73 (1H, d, J=5.2 Hz), 4.82 (1H, s), 5.37 (1H, m), 5.41 (1H, m), 5.78 (1H, m), 6.40 (1H, br)

### Example 4

### Synthesis of 2,6-(7-oxanorbornane) sultone-5-yl (2-methacryloylaminomethyl)carboxylate

The procedure of Example 1-(a) was repeated, except that 231.8 g (1.219 mol) of 5-hydroxy-2,6-norbornane sultone was changed to 240.2 g (1.250 mmol) of 5-hydroxy-7-oxanorbornane-2,6-sultone, to thereby obtain 150.0 g (0.473 mmol, white solid) of 2,6-(7-oxanorbornane) sultone-5-yl (2-methacryloylaminomethyl)carboxylate (yield with respect to 5-hydroxy-7-oxanorbornane-2,6-sultone: 37.9%).

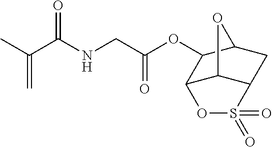 [SMILES: C=C(C)C(=O)NCC(=O)OC1C2CC3C(O2)C1OS3(=O)=O]

¹H-NMR (400 MHz, CDCl₃, TMS, ppm): 1.99 (3H, s), 2.29-2.39 (2H, m), 3.65-3.70 (1H, m), 4.12 (1H, dd, J=18.4, 5.6 Hz), 4.13 (1H, dd, J=18.4, 5.6 Hz), 4.76 (1H, d, J=4.8 Hz), 4.83 (1H, d, J=4.8 Hz), 4.95 (1H, s), 5.41 (1H, m), 5.54 (1H, m), 5.75 (1H, m), 6.22 (1H, br)

### Example 5

### Synthesis of Polymer (a)

To a three-necked flask having a capacity of 50 mL and equipped with a stirrer, a reflux condenser, and a thermometer, 4.0 g (17.2 mmol) of 2-methacryloyloxy-2-methyladamantane, 1.4 g (6.0 mmol) of 3-hydroxyadamantan-1-yl methacrylate, 6.2 g (19.8 mmol) of 2,6-norbornane sultone-5-yl (2-methacryloylaminomethyl)carboxylate, and 36.4 g of 2-butanone were added. The mixture was bubbled with nitrogen for 10 minutes. Under nitrogen atmosphere, 0.36 g (2 mmol) of 2,2′-azobisisobutyronitrile was added to the flask, and the contents were subjected to polymerization at 80° C. for 4 hours.

The thus-obtained reaction mixture was added dropwise to 200 g of methanol at room temperature with stirring. The formed precipitates were recovered through filtration. The precipitate was dried under reduced pressure (26.0 Pa) at 50° C. for 8 hours, to thereby obtain 6.0 g of polymer (a) formed of the following repeating units (each numerical value represents a mole fraction). The obtained polymer (a) was found to have a weight average molecular weight (Mw) of 9,000 and a molecular weight distribution of 1.6.

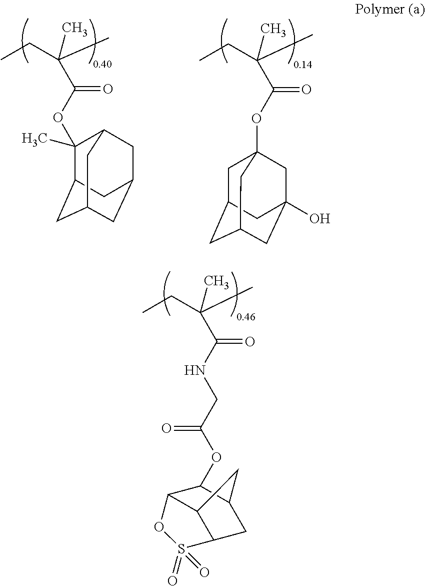

### Example 6

### Synthesis of Polymer (b)

The procedure of Example 5 was repeated, except that 6.2 g (19.8 mmol) of 2,6-norbornane sultone-5-yl (2-methacryloylaminomethyl)carboxylate was changed to 5.8 g (20.0 mmol) of 2,6-norbornane carbolactone-5-yl (2-methacryloylaminomethyl)carboxylate, to thereby obtain 6.2 g of polymer (b) formed of the following repeating units (each numerical value represents a mole fraction). The obtained polymer (b) was found to have a weight average molecular weight (Mw) of 8,800 and a molecular weight distribution of 1.6.

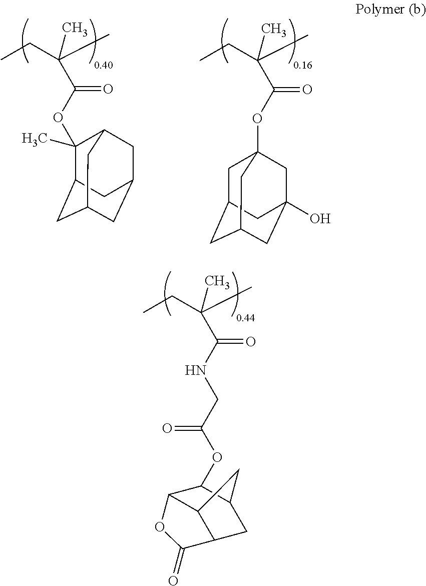

### Example 7

### Synthesis of Polymer (c)

The procedure of Example 5 was repeated, except that 6.2 g (19.8 mmol) of 2,6-norbornane sultone-5-yl (2-methacryloylaminomethyl)carboxylate was changed to 6.2 g (22.0 mmol) of 2,6-(7-oxanorbornane) carbolactone-5-yl (2-methacryloylaminomethyl)carboxylate, to thereby obtain 6.0 g of polymer (c) formed of the following repeating units (each numerical value represents a mole fraction). The obtained polymer (c) was found to have a weight average molecular weight (Mw) of 8,700 and a molecular weight distribution of 1.8.

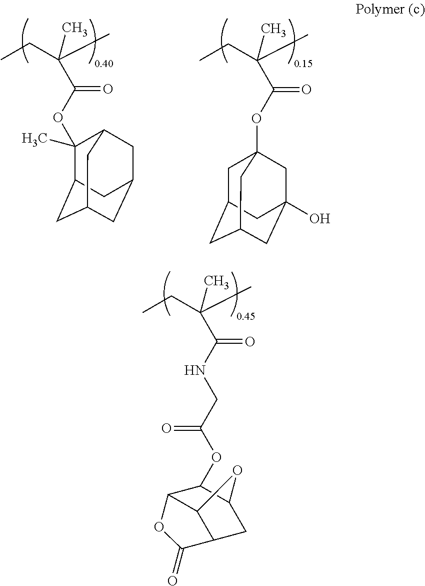

### Example 8

### Synthesis of Polymer (d)

The procedure of Example 5 was repeated, except that 6.2 g (19.8 mmol) of 2,6-norbornane sultone-5-yl (2-methacryloylaminomethyl)carboxylate was changed to 6.6 g (20.8 mmol) of 2,6-(7-oxanorbornane) sultone-5-yl (2-methacryloylaminomethyl)carboxylate, to thereby obtain 6.5 g of polymer (d) formed of the following repeating units (each numerical value represents a mole fraction). The obtained polymer (d) was found to have a weight average molecular weight (Mw) of 9,000 and a molecular weight distribution of 1.7.

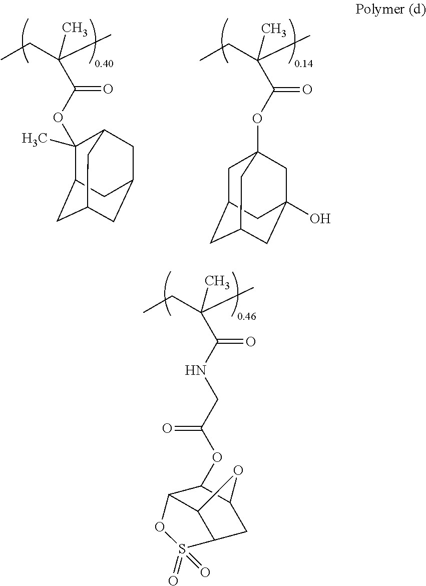

### Comparative Synthesis Example 1

### Synthesis of Polymer (e)

To a three-necked flask having a capacity of 50 mL and equipped with an electromagnetic stirrer, a reflux condenser, and a thermometer, 4.0 g (17.2 mmol) of 2-methacryloyloxy-2-methyladamantane, 1.4 g (6.0 mmol) of 3-hydroxyadamantan-1-yl methacrylate, 6.3 g (19.8 mmol) of 5-(methacryloyloxyacetoxy)-2,6-norbornane sultone, and 36.4 g of 2-butanone were added. The mixture was bubbled with nitrogen for 10 minutes. Under nitrogen atmosphere, 0.36 g (2 mmol) of 2,2′-azobisisobutyronitrile was added to the flask, and the contents were subjected to polymerization at 80° C. for 4 hours.

The thus-obtained reaction mixture was added dropwise to 220 g of methanol at room temperature with stirring. The formed precipitates were recovered through filtration. The precipitate was dried under reduced pressure (26.7 Pa) at 50° C. for 8 hours, to thereby obtain 7.3 g of polymer (e) formed of the following repeating units (each numerical value represents a mole fraction). The obtained polymer (e) was found to have a weight average molecular weight (Mw) of 9,400 and a molecular weight distribution of 1.9.

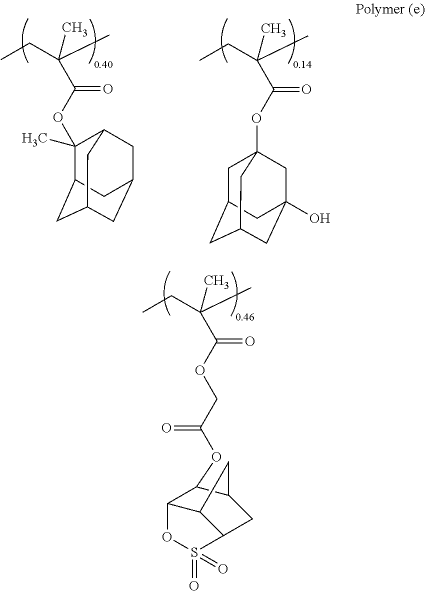

### Comparative Synthesis Example 2

### Synthesis of Polymer (f)

To a three-necked flask having a capacity of 50 mL and equipped with an electromagnetic stirrer, a reflux condenser, and a thermometer, 4.0 g (17.2 mmol) of 2-methacryloyloxy-2-methyladamantane, 1.4 g (6.0 mmol) of 3-hydroxyadamantan-1-yl methacrylate, 5.5 g (19.8 mmol) of 5-(methacryloyloxyacetoxy)-2,6-norbornane carbolactone, and 36. 4 g of 2-butanone were added. The mixture was bubbled with nitrogen for 10 minutes. Under nitrogen atmosphere, 0.36 g (2 mmol) of 2,2′-azobisisobutyronitrile was added to the flask, and the contents were subjected to polymerization at 80° C. for 4 hours.

The thus-obtained reaction mixture was added dropwise to 220 g of methanol at room temperature with stirring. The formed precipitates were recovered through filtration. The precipitate was dried under reduced pressure (26.7 Pa) at 50° C. for 8 hours, to thereby obtain 7.0 g of polymer (f) formed of the following repeating units (each numerical value represents a mole fraction). The obtained polymer (f) was found to have a weight average molecular weight (Mw) of 8,900 and a molecular weight distribution of 1.8.

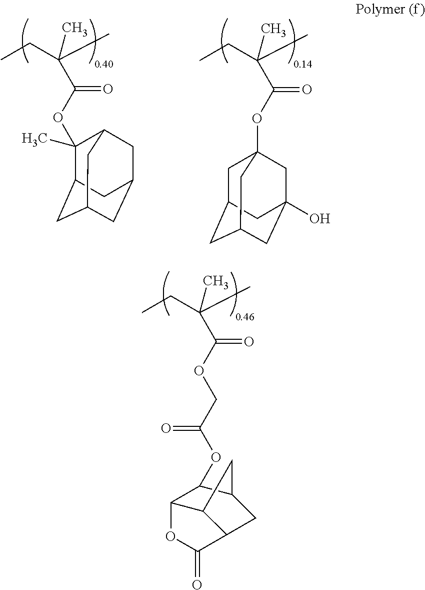

### Examples 9 to 12 and Comparative Examples 1 and 2

100 Parts by mass of each of the polymers (a) to (f) obtained in Examples 5 to 8 and Comparative Synthesis Examples 1 and 2 was mixed with 4.5 parts by mass of “TPS-109” (trade name, component: triphenylsulfonium nonafluoro-n-butanesulfonate, product of Midori Kagaku Co., Ltd.) serving as a photoacid generator, and 1896 parts by mass of a solvent mixture of propylene glycol monomethyl ether acetate/cyclohexanone (1:1 by mass) serving as a solvent. Thus, six photoresist compositions were prepared.

Each photoresist composition was separated through filtration with a membrane filter having a pore size of 0.2 μm. 6 Mass % solution of cresol novolac resin (“PS-6937,” product of Gunei Chemical Industry Co., Ltd.) in propylene glycol monomethyl ether acetate was coated onto a silicon wafer having a diameter of 10 cm through spin coating, and then baking was carried out on a hot plate at 200° C. for 90 seconds, to thereby form, on the wafer, an anti-reflection film (underlayer) having a thickness of 100 nm. The above-obtained filtrate was coated onto the wafer having the film thereon through spin coating, and prebaking was carried out on a hot plate at 130° C. for 90 seconds, to thereby form a resist film having a thickness of 300 nm. The resist film was subjected to two-beam interference exposure with ArF excimer laser having a wavelength of 193 nm. Subsequently, post-exposure baking was carried out at 130° C. for 90 seconds, and then the resultant wafer was developed with 2.38 mass % aqueous tetramethylammonium hydroxide solution for 60 seconds, to thereby form a 1:1 line and space pattern. The thus-developed wafer was cut and observed under a scanning electron microscope (SEM). There was observed the shape of the pattern with respect to exposure light for forming a 1:1 line and space having a line width of 100 nm. Also, line width roughness (LWR) was determined.

For determination of LWR, line widths were measured at a plurality of points in a measurement monitor, and the variance (3σ) of the line widths at the points was employed as an index. The shape of a cross section profile of the pattern-formed layer was observed under a scanning electron microscope (SEM) and evaluated as follows. When the patterned cross section shape had high squareness, rating “0” was assigned, whereas when the patterned cross section shape had low squareness, rating “x” was assigned. The results are shown in Table 1.

TABLE 1
Evaluation by exposure

| | | LWR | Pattern |
|---|---|---|---|
| | Polymer employed | (nm) | shape |
| Example 9 | Polymer (a) | 8.0 | ◯ |
| Example 10 | Polymer (b) | 9.5 | ◯ |
| Example 11 | Polymer (c) | 9.0 | ◯ |
| Example 12 | Polymer (d) | 7.6 | ◯ |
| Comp. Ex. 1 | Polymer (e) | 10.4 | ◯ |
| Comp. Ex. 2 | Polymer (f) | 11.2 | X |

As is clear from the aforementioned data, a resist composition containing each of the polymers (i.e., polymers (a) to (d)), the polymer being produced through polymerization of a raw material containing the acrylamide derivative (1) of the present invention, realizes formation of a resist pattern having a favorable shape and improved LWR, as compared with the case of a resist composition containing each of the polymers (i.e., polymers (e) and (f)), the polymer being produced through polymerization of a raw material not containing the acrylamide derivative (1) of the present invention. That is, the resist composition of the present invention can form a resist pattern having both high resolution and low LWR.

### INDUSTRIAL APPLICABILITY

The acrylamide derivative of the present invention is useful as a raw material of a polymer for a resist composition which realizes formation of a resist pattern having a favorable shape and improved LWR.

1: An acrylamide derivative of formula (1): 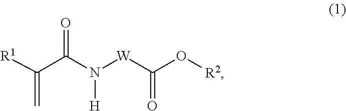
wherein
R¹ is a hydrogen atom, a methyl group, or a trifluoromethyl group:
W is a C1 to C10 alkylene group or a C3 to C10 cycloalkylene group; and
R² is a cyclic group having from 3 to 20 ring-forming atoms and is of formula (2): 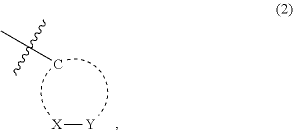
and
wherein
X is an oxygen atom or >N—R³ in which R³ is a hydrogen atom or a C1 to C5 alkyl group; and
Y is >C═O or >S(═O)ₙ in which n is an integer of from 0 to 2.

2: The acrylamide derivative according to claim 1,
wherein the acrylamide derivative is of formula (3): 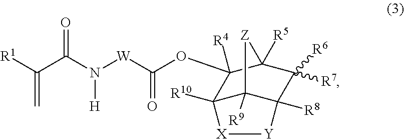
wherein each of R⁴, R⁵, R⁶, R⁸, R⁹, and R¹⁰ is a hydrogen atom, a C1 to C6 alkyl group, a C3 to C6 cycloalkyl group, a C1 to C6 alkoxy group, or an ester group;
R⁷ is a hydrogen atom, a C1 to C6 alkyl group, a C3 to C6 cycloalkyl group, a C1 to C6 alkoxy group, or —COOR^{a} in which R^{a} is a C1 to C3 alkyl group;
Z is a methylene group, an oxygen atom, or a sulfur atom; and
wavy lines are that either R⁶ or R⁷ is in an endo or exo position.

3: A polymer obtained by a process comprising polymerizing a raw material comprising the acrylamide derivative according to claim 1.

4: A photoresist composition, comprising:
the polymer according to claim 3,
a photoacid generator, and
a solvent.

5: A polymer obtained by a process comprising polymerizing a raw material comprising the acrylamide derivative according to claim 2.

6: A photoresist composition, comprising:
the polymer according to claim 5,
a photoacid generator, and
a solvent.

7: The acrylamide derivative according to claim 1,
wherein R¹ is a hydrogen atom or a methyl group.

8: The acrylamide derivative according to claim 2,
wherein R¹ is a hydrogen atom, a methyl group.

9: The acrylamide derivative according to claim 1,
wherein W is a C1 to C5 alkylene group.

10: The acrylamide derivative according to claim 2,
wherein W is a C1 to C5 alkylene group.

11: The acrylamide derivative according to claim 1,
wherein if R³ is present, R³ is a branched C3 or C4 alkyl group.

12: The acrylamide derivative according to claim 2,
wherein if R³ is present, R³ is a branched C3 or C4 alkyl group.

13: The acrylamide derivative according to claim 1,
wherein if n is present, n is 2.

14: The acrylamide derivative according to claim 2,
wherein if n is present, n is 2.

15: The acrylamide derivative according to claim 2,
wherein Z is a methylene group or an oxygen atom.

16: The acrylamide derivative according to claim 2,
wherein each of R⁴, R⁵, R⁶, R⁸, R⁹, and R¹⁰ is a hydrogen atom, a C1 to C3 alkyl group, or a C1 to C3 alkoxy group.

17: The acrylamide derivative according to claim 2,
wherein each of R⁷ is in an endo position.
